(19) United States
(12) Patent Application Publication
(10) Pub. No.: US 2021/0384398 A1
(43) Pub. Date: Dec. 9, 2021

(54) FLEXIBLE THERMOELECTRIC DEVICE, SYSTEMS THEREOF, METHODS OF MAKING, AND USES THEREOF

(71) Applicants: North Carolina State University, Raleigh, NC (US); Georgia Tech Research Corporation, Atlanta, GA (US)

(72) Inventors: HASAN SHAHARIAR, Raleigh, NC (US); JESSE S. JUR, Raleigh, NC (US); NATHAN WEINER, Raleigh, NC (US); MARK LOSEGO, Atlanta, GA (US); ANDREW SHORT, Atlanta, GA (US)

(21) Appl. No.: 17/286,326

(22) PCT Filed: Oct. 17, 2019
(86) PCT No.: PCT/US2019/056798

§ 371 Date: Apr. 16, 2021

Related U.S. Application Data
(60) Provisional application No. 62/746,883, filed on Oct. 17, 2018.

(51) Int. Cl. H01L 35/32; H01L 35/34; H01L 35/30

(52) U.S. Cl. CPC H01L 35/32; H01L 35/30; H01L 35/34

(57) ABSTRACT

Examples of flexible thermoelectric generators (TEGs), systems thereof, and methods of manufacturing the flexible TEGs are presented. The TEG devices can be used for cooling or heating. The flexible configuration allows the TEGs to conform to a wide range of surface shapes. A flexible thermoelectric generator (TEG) includes thermoelectric (TE) legs in vertical voids of a foam and conductive connectors coupled to TE legs. The TEGs can be used for cooling or heating in, e.g., cushions, mattresses, garments, footwear, carpets, flexible wraps, coolers, containers, etc.

### CROSS REFERENCE TO RELATED APPLICATIONS

This application claims priority to, and the benefit of, co-pending U.S. provisional application entitled “Flexible Thermoelectric device, systems thereof, methods of making and uses thereof” having Ser. No. 62/746,883, filed Oct. 17, 2018, the entirety of which is hereby incorporated by reference.

### BACKGROUND

Thermoelectric generators (TEGs) are solid state devices that can convert a temperature difference (or heat flux) into electrical energy through a phenomenon called the Peltier effect. TEGs have a variety of applications but not yet fully realized. As such, there exists a need for improved TEGs and fabrication processes.

### SUMMARY

Aspects of the present disclosure are related to flexible thermoelectric devices, which can be used for cooling or heating. Examples of systems, methods of making and uses of the thermoelectric devices are disclosed.

In one aspect, among others, a flexible thermoelectric generator (TEG) comprises vertical voids in a foam block, thermoelectric (TE) legs in the vertical voids, and conductive connectors coupled to TE legs. The foam block can comprise the vertical voids, wherein the vertical voids extend from a top surface to a bottom surface of the foam block. The foam block can comprise horizontal voids, wherein each horizontal void can extend into the foam block a depth as measured from either the top surface of the foam block or the bottom surface of the foam block, wherein the horizontal voids do not extend completely from the top surface of the foam block to the bottom surface of the foam block. Each horizontal void can extend a distance along the top surface or the bottom surface of the foam block, and wherein at least one end of each horizontal void overlaps a vertical void. Each end of at least one of the horizontal voids can overlap a vertical void. Each TE leg can be contained in a vertical void, wherein the TE leg can have a first surface at a first end of the TE leg and a second surface at a second end of the TE leg, wherein the first end is opposite the second end of the TE leg. The entire TE leg except for the first surface and the second surface can be in direct contact with the foam block, wherein the first surface of the TE leg can be level with the bottom of a horizontal void extending into the top surface of the foam block, and wherein the second surface of the TE leg can be level with the bottom of a horizontal void extending into the bottom surface of the foam block. Each conductive connector can be layered on the bottom of a horizontal void, wherein at least one end of each conductive connector is coupled to a first surface or a second surface of at least one of the TE legs. A thickness of each conductive connector can be less than the depth of the horizontal void.

In one or more aspects, the flexible TEG can comprise heat spreading material blocks, wherein each heat spreading material block is placed in the horizontal void on top of the conductive connector present in the horizontal void. A bottom surface of each heat spreading material block can be in direct contact with at least the conductive connector present in the horizontal void and a top surface of each heat spreading material block can be level with either the bottom surface of the foam block or the top surface of the foam block. The flexible TEG can comprise a heat sink, wherein the heat sink can be in direct contact with the top surface or the bottom surface, but not both surfaces, of the foam block and can be in direct contact with the heat spreading material blocks that are level with the surface of the foam block that is in direct contact with the heat sink. The heat sink can form an outer layer of the flexible TEG. The flexible TEG can comprise a compressive material layer, wherein the compressive material layer can be in direct contact with the top surface or the bottom surface, but not both surfaces, of the foam block and is in direct contact with the heat spreading material blocks that are level with the surface of the foam block that is in direct contact with the compressive material layer. The compressive material layer can form an outer layer of the flexible TEG opposite of the heat sink.

In various aspects, the flexible TEG can comprise a compressive material layer, wherein the compressive material layer can be in direct contact with the top surface or the bottom surface, but not both surfaces, of the foam block and can be in direct contact with the heat spreading material blocks that are level with the surface of the foam block that is in direct contact with the compressive material layer. The heat compressive material layer can form an outer layer of the flexible TEG. At least one of the horizontal voids can extend to an edge of the foam block and wherein the conductive connector in contact with the bottom surface of the horizontal void that extends to the edge of the foam block can extend a distance past the edge of the foam block and can be configured to couple to a power source. At least one additional horizontal void can extend to the edge of the foam block and wherein the conductive connector in contact with the bottom surface of the horizontal void that extends to the edge of the foam block can extend a distance past the edge of the foam block and can be configured to couple to a power source.

In some aspects, the foam block can comprises patterned scoring on the top surface, bottom surface, or both the top and the bottom surface of the foam block. The foam block can comprise a polymer, a textile, or a combination of a polymer and a textile thereof. The polymer can be an open cell or a closed cell polymer. The foam layer can be a flexible printed circuit board. The conductive connectors can comprise a conductive film or a filament of metals, a printed material composed of a metallic ink or an ink-polymer composite, a polymer film, or any combination thereof. At least one of the TE legs can be an N-type TE leg or a P-type TE leg. The heat spreading material block can comprise a metal, a polymer composite, a metal or graphene coated material, a carbon or graphene-based thermally conductive films, a highly conductive polymer film, a soft rubbery material that can be loaded with ceramic particles or materials, or any combination thereof. The heat sink can comprise a metal, a polymer composite, a metal or graphene coated material, a carbon or graphene-based thermally conductive films, a highly conductive polymer film, a soft rubbery material that can be loaded with ceramic particles or materials, or any combination thereof. The compressive material layer can comprise: a polymer, a textile, or a combination of a polymer and a textile. The total resistance across all the conductive connectors and contact resistance between the conductive connectors and the TE legs can be less than the total resistance of the TE legs. A total resistance across all the conductive connectors and contact resistance between the conductive connectors and the TE legs can be less than a total resistance of the TE legs.

In another aspect, a system comprises a plurality of the flexible TEG devices. At least one of the flexible TEG devices of the plurality of TEG devices can be coupled to a power source, and wherein each of the TEG devices of the plurality of TEG devices can be coupled to at least one other TEG device of the plurality of TEG devices. At least two of the TEG devices can be coupled in series. At least two of the TEG devices can be coupled in parallel. A cushion or a mattress can comprise one or more flexible TEG devices or a system of flexible TEG devices.

In another aspect, a method of manufacturing a flexible TEG device comprises forming vertical voids in a foam block, wherein the vertical voids extend from a top surface to a bottom surface of the foam block; forming horizontal voids in the foam block; inserting a plurality TE legs into a plurality of the vertical voids; and connecting pairs of TE legs in the plurality of TE legs with conductive connectors. Each horizontal void can extend into the foam block a depth as measured from either the top surface of the foam block or the bottom surface of the foam block, wherein the horizontal voids do not extend completely from the top surface of the foam block to the bottom surface of the foam block. Each horizontal void can extend a distance along the top surface or the bottom surface of the foam block, wherein at least one end of each horizontal void can overlap a vertical void. Each end of at least one of the horizontal voids can overlap a vertical void. A single TE leg can be inserted per vertical void, wherein the TE leg has a first surface at a first end of the TE leg and a second surface at a second end of the TE leg, wherein the first end is opposite the second end of the TE leg. The entire TE leg except for the first surface and the second surface can be in direct contact with the foam block, wherein the first surface of the TE leg can be level with the bottom of a horizontal void extending into the top surface of the foam block, and wherein the second surface of the TE leg can be level with the bottom of a horizontal void extending into the bottom surface of the foam block. Each conductive connector can be layered on the bottom of a horizontal void. At least one end of each conductive connector can be coupled to a first surface or a second surface of a TE leg and the other end of each conductive connector can be coupled to a first surface or a second surface of a different TE leg in the plurality of TE legs. A thickness of each conductive connector can be less than the depth of the horizontal void.

In one or more aspects, the method can comprise coupling a heat spreading material block to the foam block. Each heat spreading material block can be placed in the horizontal void on top of the conductive connector present in the horizontal void. A bottom surface of each heat spreading material block can be in direct contact with the heat spreading block and a top surface of each heat spreading material block can be level with either the bottom surface of the foam block or the top surface of the foam block. The method can comprise coupling a heat sink to the foam block. The heat sink can be in direct contact with the top surface or the bottom surface, but not both surfaces, of the foam block and can be in direct contact with the heat spreading material blocks that are level with the surface of the foam block that is in direct contact with the heat sink. The heat sink can form an outer layer of the flexible TEG. The method can comprise coupling a compressive material layer to the foam block. The compressive material layer can be in direct contact with the top surface or the bottom surface, but not both surfaces, of the foam block and can be in direct contact with the heat spreading material blocks that are level with the surface of the foam block that is in direct contact with the compressive material layer. The compressive material layer can form an outer layer of the flexible TEG opposite of the heat sink.

In various aspects, at least one of the horizontal voids can extend to the edge of the foam block and the conductive connector in contact with the bottom surface of the horizontal void that extends to the edge of the foam block can extend a distance past the edge of the foam block and can be configured to couple to a power source. At least one additional horizontal void can extend to the edge of the foam block and the conductive connector in contact with the bottom surface of the horizontal void that extends to the edge of the foam block can extend a distance past the edge of the foam block and can be configured to couple to a power source. The method can comprise etching or cutting a pattern on the top surface, bottom surface, or both the top and the bottom surface of the foam block. The foam block can comprise a polymer, a textile, or a combination of a polymer and a textile thereof. The conductive connectors can comprise a conductive film or a filament of metals, a printed material composed of a metallic ink or an ink-polymer composite, a polymer film, or any combination thereof. At least one of the TE legs can be an N-type TE leg or a P-type TE leg.

In some aspects, the heat spreading block can comprise a metal, a polymer composite, a metal or graphene coated material, a carbon or graphene-based thermally conductive films, a highly conductive polymer film, a soft rubbery material that can be loaded with ceramic particles or materials, or any combination thereof. The heat sink can comprise a metal, a polymer composite, a metal or graphene coated material, a carbon or graphene-based thermally conductive films, a highly conductive polymer film, a soft rubbery material that can be loaded with ceramic particles or materials, or any combination thereof. The compressive material layer can comprise a polymer, a textile, or a combination of a polymer and a textile. The TE legs can be coupled to the conductive connectors such that a total resistance across all the conductive connectors and contact resistance between the conductive connectors and the TE legs can be less than a total resistance of the TE legs.

Other systems, methods, features, and advantages of the present disclosure will be or become apparent to one with skill in the art upon examination of the following drawings and detailed description. It is intended that all such additional systems, methods, features, and advantages be included within this description, be within the scope of the present disclosure, and be protected by the accompanying claims. In addition, all optional and preferred features and modifications of the described embodiments are usable in all aspects of the disclosure taught herein. Furthermore, the individual features of the dependent claims, as well as all optional and preferred features and modifications of the described embodiments are combinable and interchangeable with one another.

### BRIEF DESCRIPTION OF THE DRAWINGS

Further aspects of the present disclosure will be readily appreciated upon review of the detailed description of its various embodiments, described below, when taken in conjunction with the accompanying drawings.

FIG. 1 shows an example of a flexible thermoelectric generator (TEG) device as described herein, in accordance with various embodiments of the present disclosure.

FIG. 2 shows images illustrating examples of a TEG cooling/heating (TEC) prototype device developed on Kapton (Polyimide) films with copper interconnects, in accordance with various embodiments of the present disclosure.

FIG. 3 illustrates the thermal profile of a 4×4 TEG (or TEC) device placed on an aluminum block without (left) and with (right) a pyrolytic graphite sheet (PGS) heat spreading layer, in accordance with various embodiments of the present disclosure.

FIG. 4 shows images of an example of a foam-based TEG (or TEC) device where the TE legs are inserted through laser-cut holes on the foam, in accordance with various embodiments of the present disclosure. The interconnects can be printed on thermoplastic polyurethane films which can be laminated on the foam.

FIG. 5 shows images illustrating an example of a fabrication process of a TEG (or TEC) device where the TE legs are inserted in a nonwoven foam (e.g., a needle punched PET nonwoven) layer, in accordance with various embodiments of the present disclosure. The etched pyralux film (Kapton film plated with copper) can be soldered to connect the TE legs.

FIG. 6 illustrates an example of the correlation between the thermoelectric temperature gradient and the series resistance of the TE legs, interconnects, contact resistance of the legs with interconnects and the optimum current, in accordance with various embodiments of the present disclosure.

FIG. 7 illustrates an example of the development of a TEG (or TEC) device made with TE legs soldered on pyralux film, the legs inserted into the nonwoven materials with pyralux film connectors, and the legs inserted into thermally stable foam with copper foil and/or copper plated fabric interconnects, in accordance with various embodiments of the present disclosure.

FIG. 8 illustrates an example of a step by step fabrication process of the foam-based TEG (or TEC) device, in accordance with various embodiments of the present disclosure. A laser cuts the holes to insert the TE legs and etches the foam for slot interconnects and solder paste. After soldering the interconnects, thermally conductive soft materials can be placed in the same slots for thermal spreading and cushioning the legs.

FIG. 9 illustrates an examples of the range of thickness of the copper foil used as the interconnects of the TE legs, and the custom-built metal-piece developed for the localized sintering of interconnects (copper foil with the TE legs), in accordance with various embodiments of the present disclosure. In addition, FIG. 9 shows finite element modeling of a TEG (or TEC) cooling device and a cross-sectional image of the fully packaged TEG (or TEC) device, in accordance with various embodiments of the present disclosure.

FIG. 10 shows an example of a comparative analysis of the total resistance of the same size TEG (or TEC) devices made with copper foil interconnects and nickel coated conductive fabric interconnects, in accordance with various embodiments of the present disclosure.

FIG. 11 shows infrared thermal images of foam based TEG (or TEC) devices made with copper foil interconnects and nickel fabric interconnects, in accordance with various embodiments of the present disclosure. The result shows that the lower resistance of the TEG (or TEC) device made with copper foil interconnects enables higher rate of cooling.

FIG. 12 illustrates an example of the variation of the cooling temperature of the TEG (or TEC) device with the increase of the current through the device, in accordance with various embodiments of the present disclosure. The device was placed on a block of aluminum (as a heat sink).

FIG. 13 illustrates examples of cold side temperature, hot side temperature, temperature differential and the resistance of the TEG (or TEC) device (copper interconnect) with the increase of current flow through the device, in accordance with various embodiments of the present disclosure.

FIG. 14 shows a comparative analysis of different versions of TEG (or TEC) devices developed with different materials and integration system, in accordance with various embodiments of the present disclosure.

FIG. 15 illustrates an example of the stress concentration at the connection points of the interconnects and the TE legs through the development of pulling tension while the device is bent, in accordance with various embodiments of the present disclosure.

FIG. 16 shows an example of an integration process of adhesive material around the soldering area of the interconnect and the leg connection (junctions) to mitigate the stress concentration at the junctions, in accordance with various embodiments of the present disclosure. The crimped metal foil interconnect (bottom right) is capable of extending when the device is bent.

FIG. 17 shows an example of a set-up of the TEG (or TEC) device on a foam material with the integration of a thermal spreading layer, in accordance with various embodiments of the present disclosure.

FIG. 18 shows examples of IR thermal images of the cold side of the TEG (or TEC) device with increasing current through the device, in accordance with various embodiments of the present disclosure. The device was evaluated on a foam block and without the integration of the thermal spreading layer, in accordance with various embodiments of the present disclosure.

FIG. 19 shows examples of IR thermal images of the cold side of the TEG (or TEC) device of FIG. 18 with the increase of the current through the device. The device was integrated with the thermal spreading layer and evaluated on a foam block, in accordance with various embodiments of the present disclosure.

FIG. 20 shows an example of the integration process of a thermal adhesive film layer around the TE leg areas, in accordance with various embodiments of the present disclosure.

FIG. 21 illustrates examples of the manufacturing process of inserting TE legs with a pick-and-place robot and the process of die-cutting the thin-metal foil to make the interconnects, in accordance with various embodiments of the present disclosure.

FIG. 22 shows an example of the individual layers of a 6×6 TEG (or TEC) foam-device (36 total TE legs), in accordance with various embodiments of the present disclosure.

FIG. 23 shows an example of a laser cutting process for creating a Kirigami cut-design around the legs and interconnects of the TEG (or TEC) device to increase the flexibility of the device, in accordance with various embodiments of the present disclosure.

FIG. 24 shows an example of the mechanical compression (compressed & bent) test of the TEG (or TEC) device when it is place on a foam (e.g., a mattress), in accordance with various embodiments of the present disclosure.

FIG. 25 illustrates examples of the resistance of the kirgami-cut or flex cut around the legs and interconnects of the TEG (or TEC) device, which provide the bendability and compressibility to the device, in accordance with various embodiments of the present disclosure. The mechanical compression test data shows that the device with flex-cut have very insignificant change of internal resistance after compressing the device integrated foam (50% compression) to 6000 cycles.

FIG. 26 shows examples of thermal image measurement set up of the 6×6 flex-cut TEG (or TEC) devices, in accordance with various embodiments of the present disclosure.

FIG. 27 shows an example of the comparison of thermal images of the TEG (or TEC) device tests on a foam mattress with and without thermal spreading layer (e.g., a thermally conductive fabric), in accordance with various embodiments of the present disclosure.

FIGS. 28-31 show examples of various TEG (or TEC) device configurations, in accordance with various embodiments of the present disclosure.

### DETAILED DESCRIPTION

Before the present disclosure is described in greater detail, it is to be understood that this disclosure is not limited to particular embodiments described, and as such may, of course, vary. It is also to be understood that the terminology used herein is for the purpose of describing particular embodiments only, and is not intended to be limiting.

Where a range of values is provided, it is understood that each intervening value, to the tenth of the unit of the lower limit unless the context clearly dictates otherwise, between the upper and lower limit of that range and any other stated or intervening value in that stated range, is encompassed within the disclosure. The upper and lower limits of these smaller ranges may independently be included in the smaller ranges and are also encompassed within the disclosure, subject to any specifically excluded limit in the stated range. Where the stated range includes one or both of the limits, ranges excluding either or both of those included limits are also included in the disclosure.

Unless defined otherwise, all technical and scientific terms used herein have the same meaning as commonly understood by one of ordinary skill in the art to which this disclosure belongs. Although any methods and materials similar or equivalent to those described herein can also be used in the practice or testing of the present disclosure, the preferred methods and materials are now described.

All publications and patents cited in this specification are cited to disclose and describe the methods and/or materials in connection with which the publications are cited. All such publications and patents are herein incorporated by references as if each individual publication or patent were specifically and individually indicated to be incorporated by reference. Such incorporation by reference is expressly limited to the methods and/or materials described in the cited publications and patents and does not extend to any lexicographical definitions from the cited publications and patents. Any lexicographical definition in the publications and patents cited that is not also expressly repeated in the instant application should not be treated as such and should not be read as defining any terms appearing in the accompanying claims. The citation of any publication is for its disclosure prior to the filing date and should not be construed as an admission that the present disclosure is not entitled to antedate such publication by virtue of prior disclosure. Further, the dates of publication provided could be different from the actual publication dates that may need to be independently confirmed.

As will be apparent to those of skill in the art upon reading this disclosure, each of the individual embodiments described and illustrated herein has discrete components and features which may be readily separated from or combined with the features of any of the other several embodiments without departing from the scope or spirit of the present disclosure. Any recited method can be carried out in the order of events recited or in any other order that is logically possible.

It should be noted that ratios, concentrations, amounts, and other numerical data can be expressed herein in a range format. It will be further understood that the endpoints of each of the ranges are significant both in relation to the other endpoint, and independently of the other endpoint. It is also understood that there are a number of values disclosed herein, and that each value is also herein disclosed as “about” that particular value in addition to the value itself. For example, if the value “10” is disclosed, then “about 10” is also disclosed. Ranges can be expressed herein as from “about” one particular value, and/or to “about” another particular value. Similarly, when values are expressed as approximations, by use of the antecedent “about,” it will be understood that the particular value forms a further aspect. For example, if the value “about 10” is disclosed, then “10” is also disclosed.

Where a range is expressed, a further aspect includes from the one particular value and/or to the other particular value. Where a range of values is provided, it is understood that each intervening value, to the tenth of the unit of the lower limit unless the context clearly dictates otherwise, between the upper and lower limit of that range and any other stated or intervening value in that stated range, is encompassed within the disclosure. The upper and lower limits of these smaller ranges may independently be included in the smaller ranges and are also encompassed within the disclosure, subject to any specifically excluded limit in the stated range. Where the stated range includes one or both of the limits, ranges excluding either or both of those included limits are also included in the disclosure. For example, where the stated range includes one or both of the limits, ranges excluding either or both of those included limits are also included in the disclosure, e.g. the phrase “x to y” includes the range from ‘x’ to ‘y’ as well as the range greater than ‘x’ and less than ‘y’. The range can also be expressed as an upper limit, e.g. ‘about x, y, z, or less' and should be interpreted to include the specific ranges of ‘about x’, ‘about y’, and ‘about z’ as well as the ranges of ‘less than x’, less than y’, and ‘less than z’. Likewise, the phrase ‘about x, y, z, or greater’ should be interpreted to include the specific ranges of ‘about x’, ‘about y’, and ‘about z’ as well as the ranges of ‘greater than x’, greater than y’, and ‘greater than z’. In addition, the phrase “about ‘x’ to ‘y’”, where ‘x’ and ‘y’ are numerical values, includes “about ‘x’ to about ‘y’”.

It should be noted that ratios, concentrations, amounts, and other numerical data can be expressed herein in a range format. It will be further understood that the endpoints of each of the ranges are significant both in relation to the other endpoint, and independently of the other endpoint. It is also understood that there are a number of values disclosed herein, and that each value is also herein disclosed as “about” that particular value in addition to the value itself. For example, if the value “10” is disclosed, then “about 10” is also disclosed. Ranges can be expressed herein as from “about” one particular value, and/or to “about” another particular value. Similarly, when values are expressed as approximations, by use of the antecedent “about,” it will be understood that the particular value forms a further aspect. For example, if the value “about 10” is disclosed, then “10” is also disclosed.

It is to be understood that such a range format is used for convenience and brevity, and thus, should be interpreted in a flexible manner to include not only the numerical values explicitly recited as the limits of the range, but also to include all the individual numerical values or sub-ranges encompassed within that range as if each numerical value and sub-range is explicitly recited. To illustrate, a numerical range of “about 0.1% to 5%” should be interpreted to include not only the explicitly recited values of about 0.1% to about 5%, but also include individual values (e.g., about 1%, about 2%, about 3%, and about 4%) and the sub-ranges (e.g., about 0.5% to about 1.1%; about 5% to about 2.4%; about 0.5% to about 3.2%, and about 0.5% to about 4.4%, and other possible sub-ranges) within the indicated range.

As used herein, “about,” “approximately,” “substantially,” and the like, when used in connection with a numerical variable, can generally refers to the value of the variable and to all values of the variable that are within the experimental error (e.g., within the 95% confidence interval for the mean) or within +/−10% of the indicated value, whichever is greater. As used herein, the terms “about,” “approximate,” “at or about,” and “substantially” can mean that the amount or value in question can be the exact value or a value that provides equivalent results or effects as recited in the claims or taught herein. That is, it is understood that amounts, sizes, formulations, parameters, and other quantities and characteristics are not and need not be exact, but may be approximate and/or larger or smaller, as desired, reflecting tolerances, conversion factors, rounding off, measurement error and the like, and other factors known to those of skill in the art such that equivalent results or effects are obtained. In some circumstances, the value that provides equivalent results or effects cannot be reasonably determined. In general, an amount, size, formulation, parameter or other quantity or characteristic is “about,” “approximate,” or “at or about” whether or not expressly stated to be such. It is understood that where “about,” “approximate,” or “at or about” is used before a quantitative value, the parameter also includes the specific quantitative value itself, unless specifically stated otherwise.

Embodiments of the present disclosure will employ, unless otherwise indicated, techniques of physics, engineering (e.g. electrical engineering and the like), chemistry, and the like, which are within the skill of the art. Such techniques are explained fully in the literature.

### DISCUSSION

Thermoelectric generators (TEGs) are solid-state devices that can convert a temperature difference (or heat flux) into electrical energy through a phenomenon called the Peltier effect. TEGs have a variety of applications but not all have yet been fully realized. Commercially available TEGs are rigid and very expensive for applications that require the device be employed over a large surface area. As such, there exists a need for improved TEGs and fabrication processes.

With that said, described herein are flexible TEG devices that can be used for energy harvesting and solid-state heating and cooling applications. Also described herein are manufacturing processes that can be scalable and thus provide economic production of the flexible TEG (or TEC) devices described herein. Other compositions, compounds, methods, features, and advantages of the present disclosure will be or become apparent to one having ordinary skill in the art upon examination of the following drawings, detailed description, and examples. It is intended that all such additional compositions, compounds, methods, features, and advantages be included within this description, and be within the scope of the present disclosure.

Flexible TEG Devices and Systems

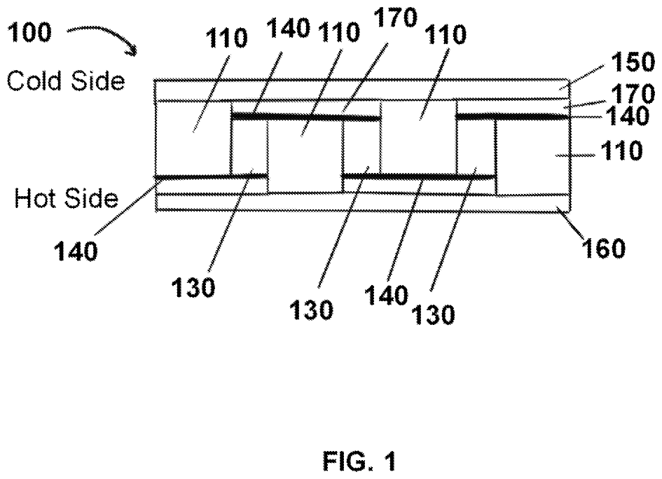

Discussion of the flexible TEG (or TEC) device begins with FIG. 1, which shows several aspects of a flexible TEG (or TEC) device. Described herein are flexible thermoelectric generators (TEGs) 100 that can include a foam block 110, where the foam block 110 can include vertical voids, wherein the vertical voids can extend from a top surface to a bottom surface of the foam block 110; and horizontal voids, wherein each horizontal void can extend into the foam block 110 a depth as measured from either the top surface of the foam block 110 or the bottom surface of the foam block 110, wherein the horizontal void does not extend completely from the top surface of the foam block 110 to the bottom surface of the foam block 110, wherein each horizontal void can extend a distance along the top surface or the bottom surface of the foam block 110, wherein at least one end of each horizontal voids can overlap a vertical void, wherein each end of at least one of the horizontal voids can overlap a vertical void; TE legs 130, wherein at least one TE leg 130 can be contained in a vertical void, wherein the TE leg 130 has a first surface at a first end of the TE leg 130 and a second surface at a second end of the TE leg 130, wherein the first end is opposite the second end of the TE leg 130, wherein the entire TE leg 130 except for the first surface and the second surface can be in direct contact with the foam block 110 and thus filling the vertical void, wherein the first surface of the TE leg 130 can be about level with the bottom of a horizontal void extending into the top surface of the foam block 110, and wherein the second surface of the TE leg 130 can be about level with the bottom of a horizontal void extending into the bottom surface of the foam block 110; and conductive connectors 140, wherein each conductive connector 140 can be layered on the bottom of a horizontal void, wherein at least one end of each conductive connector 140 can be coupled to a first surface or a second surface of a TE leg 130, wherein the thickness of each conductive connector 140 is less than the depth of the horizontal void. In some implementations, the foam block 110 can be a flexible printed circuit board.

The flexible TEG 100 can further include a heat spreading material block 170, wherein each heat spreading block 170 can be placed in the horizontal void on top of the conductive connector 140 present in the horizontal void, wherein a bottom surface of each heat spreading material block 170 is in direct contact with at least the conductive connector 140 and a top surface of each heat spreading material block is level with either the bottom surface of the foam block 110 or the top surface of the foam block 110.

The flexible TEG 100 can further include a heat sink 160, wherein the heat sink 160 can be in direct contact with the top surface or the bottom surface, but not both surfaces, of the foam block 110 and can be in direct contact with the heat spreading material blocks 170 that are level with the surface of the foam block 110 that is in direct contact with the heat sink 160, wherein the heat sink 160 can form an outer layer of the flexible TEG 100.

The flexible TEG 100 can further include a compressive material layer 150, wherein the compressive material layer 150 is in direct contact with the top surface or the bottom surface, but not both surfaces, of the foam block 110 and is in direct contact with the heat spreading material blocks 170 that are level with the surface of the foam block 110 that is in direct contact with the compressive material layer 150, wherein the compressive material layer 150 can form an outer layer of the flexible TEG 100 opposite of the heat sink 160.

In some embodiments of the flexible TEG 100, at least one of the horizontal voids can extend to the edge of the foam block 110 and wherein the conductive connector 140 that is in contact with the bottom surface of the horizontal void that extends to the edge of the foam block 110 can extend a distance past the edge of the foam block 110 and can be configured to couple to a power source. In some embodiments of the flexible TEG 100, at least one additional horizontal void can extend to the edge of the foam block 110 and wherein the conductive connector 140 in contact with the bottom surface of the horizontal void that extends to the edge of the foam block 110 can extend a distance past the edge of the foam block 110 and can be configured to couple to a power source.

In some embodiments of the flexible TEG device 100, the foam block 110 can further include patterned scoring on the top surface, bottom surface, or both the top and the bottom surface of the foam block. In some embodiments, the pattern can be a Kirigami styled pattern. The pattern can be a geometric pattern. Cut dimensions and/or shaping can allow for improved and/or altered bending and/or folding of the device. This can allow the device to conform around and/or onto planar and curvilinear surfaces.

The foam block can be made of any suitable materials. Suitable materials can include, but are not limited to, polymers (including, but not limited to, polymer gels, closed or open foam materials), textiles (including, but not limited to, nonwoven textiles, woven textiles, knits, textiles that include spacer fabrics and/or multilayered structures. In some aspects, multiple layers can be coupled or otherwise attached together using, e.g., an adhesive material.

The conductive connectors can be made of any suitable materials. Suitable materials can include but are not limited to, conductive film or filaments of metals (including, but not limited to, Ag, Cu, Au, and combinations thereof). Additionally, printed materials composed of metallic ink or ink-polymer composites can be directly printed and/or patterned directly on the structure supporting the thermoelectric legs in the polymer films and/or on polymer films that can be placed between the thermoelectric legs. The conductive connector can be linear or straight between the ends of the conductive connector. The conductive connector can be curved between the ends of the conductive connector. The conductive connector can be angled at one or more points, e.g., zig-zagged between the ends of the conducive connector. The conductive connector can be any other crimped shape that can provide stretchability of the interconnect without increasing the resistance of the device while bent.

As previously discussed, the flexible TEG device 100 can include TE legs 130. In some embodiments, at least one of the TE legs 130 is an N-type TE leg. In some embodiments, at least one of the TE legs 130 is a P-type TE leg. In some aspects, the flexible TEG device 100 includes both N-type and P-type TE legs. In aspects, the N-type and P-type legs can be put in series. Each leg (and thus each vertical void) can be spaced from each other by a distance in any direction. In some embodiments, the spacing in each direction can be the same (e.g., homogenous or uniform). In some embodiments, the spacing in at least two directions can be different from each other (e.g., heterogeneous or non-uniform). In some embodiments, the spacing in at least two directions can be the same. In some embodiments, the spacing in at least two directions can be different (also heterogeneous). The distance between any two TE legs 130 can range from about 0.1 mm to about 50 mm. In some aspects, the resistance of the interconnect and joint (e.g., a soldering joint) can be less than that of a corresponding thermoelectric leg.

As previously discussed, the flexible TEG device 100 can include heat spreading material blocks 170. The heat spreading material blocks 170 can be made of a suitable material. Suitable materials can include but are not limited to, materials that have a thermal conductivity of greater than about 1 W/m/K (air) or greater than that of the material supporting the thermoelectric legs. This can include metals, polymer composites (e.g., metal or carbon flake), metal or graphene coated materials, carbon or graphene based thermally conductive films, highly conductive polymer films, and/or soft rubbery materials that can be loaded with ceramic particles or materials. Other suitable materials will be appreciated by those of ordinary skill in the art in view of this description.

As previously discussed, the flexible TEG device 100 can include a heat sink 160. The heat sink 160 can be made of a suitable material. Suitable materials can include but are not limited to, materials that have a thermal conductivity of greater than about 1 W/m/K (air) or greater than that of the material supporting the thermoelectric legs. This can include metals, polymer composites (e.g., metal or carbon flake), metal or graphene coated materials, carbon or graphene based thermally conductive films, highly conductive polymer films, soft rubbery materials that can be loaded with ceramic particles or materials. These materials can also be structured to permit heat convection and further enhance heat removal. These materials can also have photonic or emissive properties that improve the radiative removal of heat. Other suitable materials will be appreciated by those of ordinary skill in the art in view of this description.

As previously discussed, the flexible TEG device 100 can include a compressive material layer 150. The compressive material layer 150 can be made of a suitable material. Suitable materials can include but are not limited to, polymers (including but not limited to polymer sheets, rubber sheets, polymer gels, closed and open cell foam materials), textiles (including but not limited to nonwoven materials, knits, and woven materials). Using materials with low thermal conductivity (e.g., less than 1 W/m/K, less than 0.8 W/m/K, less than 0.5 W/m/K, or less than 0.1 W/m/K) can assist in the cooling or heating operations of the TEG device 100. For example, the use of open foams and/or textiles can reduce heat leakage from the hot side to the cold side of the TEG device 100. Fully dense materials can make it easier for heat to leak back to the cold side. In some aspects, the material can be compressed itself while not impeding the compression of an underlying material. The compressive material layer 150 should also be flexible allowing for bending and movement of the TEG device 100 during installation and use. The compressive material layer 150 can provide electrical isolation so that the conductive elements (e.g., TE legs 130 and conductive connectors 140) to avoid electrical shorts in the TEG device 100.

To operate the flexible TEG device 100 described herein as a solid state cooling TEG (or TEC), the flexible TEG 100 can be configured such that the total resistance across all the conductive connectors 140 and any soldering contacts and contact resistance between the conductive connectors 140 and the TE legs 130 is less than the total resistance of the TE legs 130. The materials of the conductive connectors and/or leg spacing can be chosen to achieve such a total resistance.

The thermoelectric cooling phenomenon can be more prominent than joule heating (the I²R term in equation 1 below

$$\underline{Heat Pumping at Cold Side} \\ {Q}_{c} = 2 N * [ α {T}_{C} I - \frac{1}{2} {I}^{2} R - K ( {T}_{H} - {T}_{C} ) ] \\ \underline{Geometric Factors} \\ R = \frac{ρ L}{A} K = \frac{κ A}{L} \\ \underline{COP} \\ COP = \frac{Cooling Power}{Power Input} = \frac{{Q}_{c}}{P} \\ \underline{Parameters} \\ ρ \text{-} electrical resistivity \\ κ \text{-} thermal conductivity \\ α \text{-} Seeback coefficient \\ T \text{-} temperature \\ A \text{-} area of thermoelement \\ L \text{-} length of thermoelement \\ N \text{-} number of thermocouples \qquad ( Eq . 1 )$$

In one embodiment, copper foil of about 1 mm thickness can be used as the conductive connector 140. The conductive connectors 140 can have a 10 mm length and about a 2 mm width. The legs can be spaced homogenously from about 5 mm to about 20 mm apart. This can be measured from the end of each leg or from the middle of each leg. In other implementations, the conductive connectors 140 can be provided by, e.g., preprinted flexible circuit boards or printed electronics (e.g., using direct jet, screen printing, etc.) In some embodiments, a standard solder paste can be used to connect the TE legs 130. In some embodiments, a thermoplastic polyurethane film can be used as an adhesive support layer around the conductive connectors. A thermally conductive silicone material can be used as the heat spreading material block 170 as well as the compressive material layer 150. In some embodiments, a laser etched Kirigami inspired design can be scored on the top and/or bottom surface of the foam block 110. In some aspects, a Cu film can be connected to one or more TE legs and can be stabilized with an adhesive base on foam that can be included around one or more of the TE legs 130.

Also described herein are systems that can include a plurality of the flexible TEG devices 100 described herein, wherein at least one of the flexible TEG devices 100 of the plurality of TEG devices 100 can be coupled to a power source, and wherein each of the TEG devices of the plurality of TEG devices 100 can be coupled to at least one other TEG device 100 of the plurality of TEG devices 100. In some embodiments, at least two of the TEG devices 100 can be coupled in series. In some embodiments, at least two of the TEG devices 100 can be coupled in parallel. The arrangement of the flexible TEG devices 100 can be determined based upon the power and/or voltage levels during operation.

Any of the TEG devices 100 or systems thereof described herein can be incorporated into an article. In some aspects, the article can be a cushion, mattress, a garment (including but not limited to an inner garment (e.g., shirt, underwear, base layers etc.), outer garment (e.g., jackets, pants, sweaters (outer shirts), hats, gloves, etc.), shoes and shoe liners, carpets, flexible wraps for use on a subject (e.g., bandages, support wraps), flexible wraps that can be used on an inanimate object (e.g., a wrap for a beverage container, lining of a cooler or bag, etc.), and in any other article that currently uses or can use foam, a spacer fabric, 3D fabric, nonwoven, rubber or film.

Methods of Manufacturing the TEG Devices and Systems

Also described herein are methods of manufacturing the TEG devices and systems thereof described herein. In some embodiments, the method can include forming vertical voids in a foam block, wherein the vertical voids extend from a top surface to a bottom surface of the foam block; forming horizontal voids in the foam block, wherein each horizontal void extends into the foam block a depth as measured from either the top surface of the foam block or the bottom surface of the foam block, wherein the horizontal voids do not extend completely from the top surface of the foam block to the bottom surface of the foam block, wherein each horizontal void extends a distance along the top surface or the bottom surface of the foam block, wherein at least one end of each horizontal void overlaps a vertical void, wherein each end of at least one of the horizontal voids overlaps a vertical void; inserting a plurality TE legs into a plurality of the vertical voids, wherein a single TE leg is inserted per vertical void, wherein the TE leg has a first surface at a first end of the TE leg and a second surface at a second end of the TE leg, wherein the first end is opposite the second end of the TE leg, wherein the entire TE leg except for the first surface and the second surface is in direct contact with the foam block, wherein the first surface of the TE leg is level with the bottom of a horizontal void extending into the top surface of the foam block, and wherein the second surface of the TE leg is level with the bottom of a horizontal void extending into the bottom surface of the foam block; and connecting pairs of TE legs in the plurality of TE legs with conductive connectors, wherein each conductive connector is layered on the bottom of a horizontal void, wherein at least one end of each conductive connector is coupled to a first surface or a second surface of a TE leg and wherein the other end of each conductive connector is coupled to a first surface or a second surface of a different TE leg in the plurality of TE legs, wherein the thickness of each conductive connector is less than the depth of the horizontal void.

The method can further include the step of coupling a heat spreading block to the foam block, wherein each heat spreading block is placed in the horizontal void on top of the conductive connector present in the horizontal void, wherein a bottom surface of each heat spreading block is in direct contact with the heat spreading block and a top surface of each heat spreading block is level with either the bottom surface of the foam block or the top surface of the foam block.

The method can further include the step of coupling a heat sink to the foam block, wherein the heat sink is in direct contact with the top surface or the bottom surface, but not both surfaces, of the foam block and is in direct contact with the heat spreading material blocks that are level with the surface of the foam block that is in direct contact with the heat sink, wherein the heat sink forms an outer layer of the flexible TEG.

The method can further include the step of coupling a compressive material layer to the foam block, wherein the compressive material layer is in direct contact with the top surface or the bottom surface, but not both surfaces, of the foam block and is in direct contact with the heat spreading material blocks that are level with the surface of the foam block that is in direct contact with the compressive material layer, wherein the compressive material layer forms an outer layer of the flexible TEG opposite of the heat sink.

In some embodiments, at least one of the horizontal voids extends to the edge of the foam block and wherein the conductive connector in contact with the bottom surface of the horizontal void that extends to the edge of the foam block extends a distance past the edge of the foam block and is configured to couple to a power source. In some embodiments, at least one additional horizontal void extends to the edge of the foam block and wherein the conductive connector in contact with the bottom surface of the horizontal void that extends to the edge of the foam block extends a distance past the edge of the foam block and is configured to couple to a power source. The TEG device can have one or more termination points, which are where the TEG device is coupled to a power supply. The termination point(s) can exist at any point in the TEG device so long as there is at least two TE legs in series.

The method can further include the step etching (or cutting) a pattern on the top surface, bottom surface, or both the top and the bottom surface of the foam block. This can be completed using laser etching, chemical etching, or other suitable etching (or cutting) techniques. The pattern can also be formed on the top surface, bottom surface, or both the top and bottom surface of the foam block by other manufacturing techniques such as molding based manufacturing processes or 3D printing techniques. Such techniques will be appreciated by those of ordinary skill in the art in view of the description provided herein.

In some embodiments of the flexible TEG device 100, the foam block 110 can further include patterned scoring on the top surface, bottom surface, or both the top and the bottom surface of the foam block. In some embodiments, the pattern can be a Kirigami-styled pattern. The pattern can be a geometric pattern. Cut dimensions and/or shaping can allow for improved and/or altered bending and/or folding of the device. This can allow the device to conform around and/or onto planar and curvilinear surfaces.

The foam block can be made of any suitable materials. Suitable materials can include, but are not limited to, polymers (including, but not limited to, polymer gels, closed or open foam materials), textiles (including, but not limited to, nonwoven textiles, woven textiles, knits, textiles that include spacer fabrics and/or multilayered structures. In some aspects, multiple layers can be coupled or otherwise attached together using an adhesive material. The conductive connectors can be made of any suitable materials. Suitable materials can include, but are not limited to, conductive film or filaments of metals (including, but not limited to, Ag, Cu, Au, and combinations thereof). Additionally, printed materials composed of metallic ink or ink-polymer composites that can be directly printed and/or patterned directly on the structure supporting the thermoelectric legs in the polymer films and/or on polymer films that can be placed between the thermoelectric legs.

As previously discussed, the flexible TEG device 100 can include TE legs 130. In some embodiments, at least one of the TE legs 130 is an N-type TE leg. In some embodiments, at least one of the TE legs 130 is a P-type TE leg. In some aspects, the flexible TEG device 100 includes both N-type and P-type TE legs. In some aspects the TEG leg can be composed at least partially or entirely of bismuth telluride. In some aspects, the TE leg(s) can be made of any material that can be placed in series and have an absolute Seebeck coefficient difference that is greater that zero. In some aspects, the TE legs can be a metal or organic conductor or semiconductor in ceramic or bulk form. In some aspects, the TE legs can be composed, at least partially or entirely, of an ink. Each leg (and thus each vertical void) can be spaced from each other by a distance in any direction. In some embodiments, the spacing in each direction can be the same (e.g., homogenous or uniform). In some embodiments, the spacing in at least two directions can be different from each other (e.g., heterogeneous or non-uniform). In some embodiments, the spacing in at least two directions can be the same. In some embodiments, the spacing in at least two directions can be different (also heterogeneous). The distance between any two TE legs 130 can range from 0.1 mm to 50 mm. The resistance of the interconnect and joint (e.g. a soldering joint) can be less than that of a corresponding thermoelectric leg.

As previously discussed, the flexible TEG device 100 can include heat spreading material blocks 170. The heat spreading material blocks 170 can be made of a suitable material. Suitable materials can include but are not limited to, materials that have a thermal conductivity of greater than about 1 W/m/K (air) or that of the material supporting the thermoelectric legs. This can include metals, polymer composites (e.g. metal or carbon flake), metal or graphene coated materials, carbon or graphene based thermally conductive films, highly conductive polymer films, soft rubbery materials that can be loaded with ceramic particles or materials. Other suitable materials will be appreciated by those of ordinary skill in the art in view of this description.

As previously discussed, the flexible TEG device 100 can include a heat sink 160. The heat sink 160 can be made of a suitable material. Suitable materials can include but are not limited to, materials that have a thermal conductivity of greater than about 1 W/m/K (air) or that of the material supporting the thermoelectric legs. This can include metals, polymer composites (e.g. metal or carbon flake), metal or graphene coated materials, carbon or graphene based thermally conductive films, highly conductive polymer films, soft rubbery materials that can be loaded with ceramic particles or materials. Other suitable materials will be appreciated by those of ordinary skill in the art in view of this description.

As previously discussed, the flexible TEG device 100 can include a compressive material layer 150. The compressive material layer 150 can be made of a suitable material. Suitable materials can include but are not limited to, polymers (including but not limited to polymer gels, closed and open cell foam materials), textiles (including but not limited to nonwoven materials, knits, and woven materials). In some aspects, the material can be compressed itself while not impeding the compression of an underlying material.

The method can include the step of coupling the conductive connectors and TE legs using soldering, where the ends of the conductive connective connector are soldered to the ends of the TE legs.

### EXAMPLES

Now having described the embodiments of the present disclosure, in general, the following Examples describe some additional embodiments of the present disclosure. While embodiments of the present disclosure are described in connection with the following examples and the corresponding text and figures, there is no intent to limit embodiments of the present disclosure to this description. On the contrary, the intent is to cover all alternatives, modifications, and equivalents included within the spirit and scope of embodiments of the present disclosure.

### Example 1

FIG. 1 shows an embodiment of a flexible TEG device as described herein. The TEG device can be used as a cooling and/or heating (TEC) device. The TEG (or TEC) device includes a plurality of TE legs interconnected by conductive connectors extending between ends of adjacent TE legs in an alternating fashion on opposite sides of the device. In this configuration, the TEC device can provide cooling or heating on one side of the device through thermoelectric operation of the interconnected TE legs.

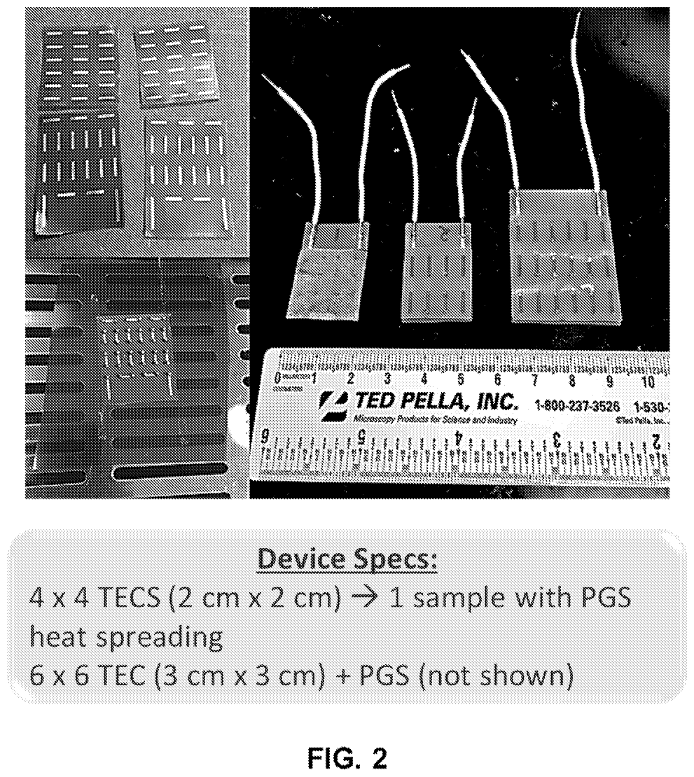

FIG. 2 shows the TEC prototype devices developed on Kapton (Polyimide) films with copper interconnects. TEC devices including 4×4 and 6×6 arrays of interconnected TE legs are shown in the images. A layer of PGS distributed over the conductive interconnects aids in evenly distributing the heating or cooling effects of the TEC device.

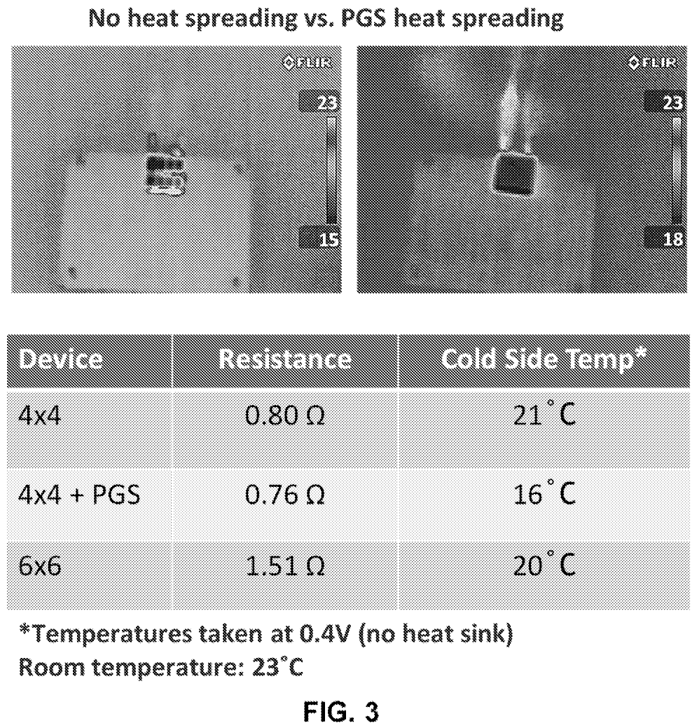

FIG. 3 shows the demonstration of the thermal profile of a 4×4 TEC device placed on an aluminum block without (left) & with (right) a PGS heat spreading layer. The images illustrate the effect of the PCS layer in evenly distributing the cooling over and between the conductive interconnects of the TEC device. As indicated in the table, the PCS layer also resulted in a lower cooling temperature.

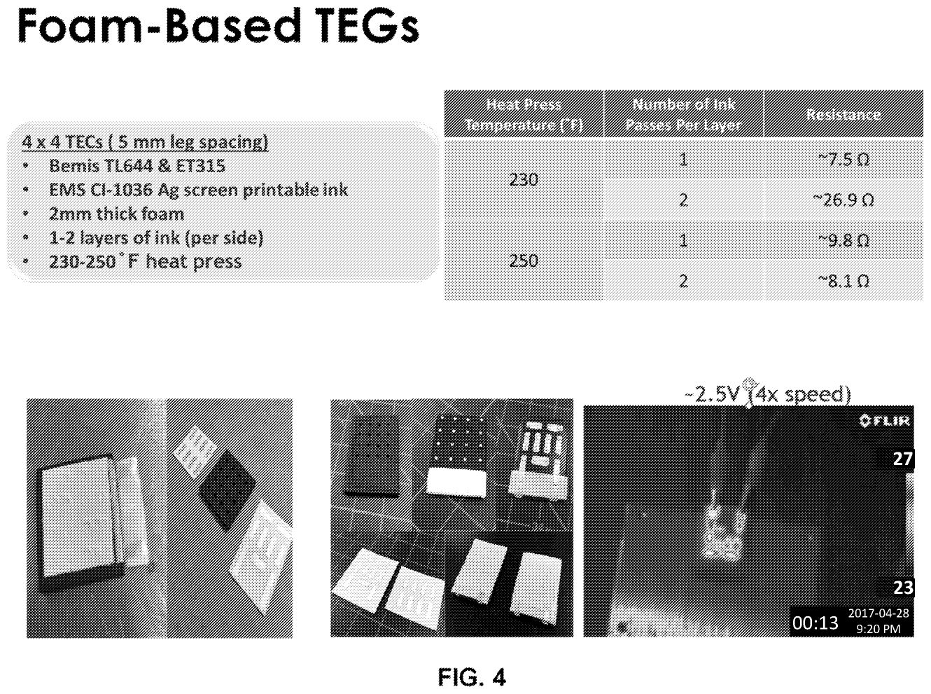

FIG. 4 shows the foam-based TEC device where the TE legs are inserted through laser-cut holes on the foam. The interconnects can be printed on thermoplastic polyurethane films which can be laminated on the foam. Images and information are provided for the fabricated TEC device, and a thermal image illustrates heating of the TEC device.

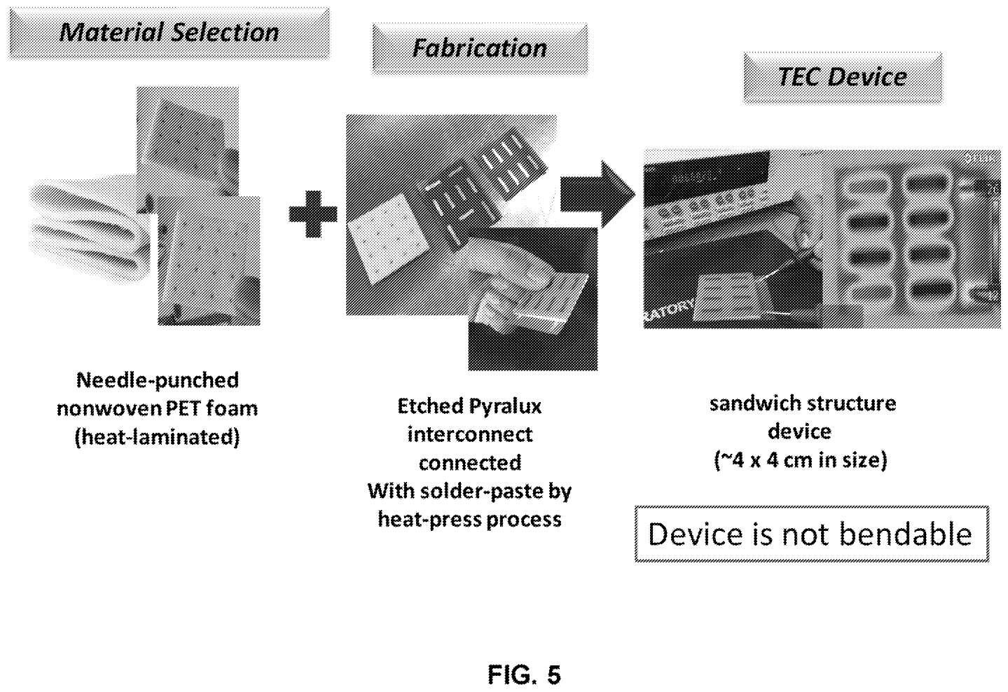

FIG. 5 shows fabrication process of TEC device where the TE legs are inserted in a selected material such as a nonwoven foam (e.g., a needle punched PET nonwoven) layer during fabrication. The etched pyralux film (Kapton film plated with copper) is soldered to connect the TE legs (e.g., using a heat press process). The film may limit the flexibility of the finished TEC device.

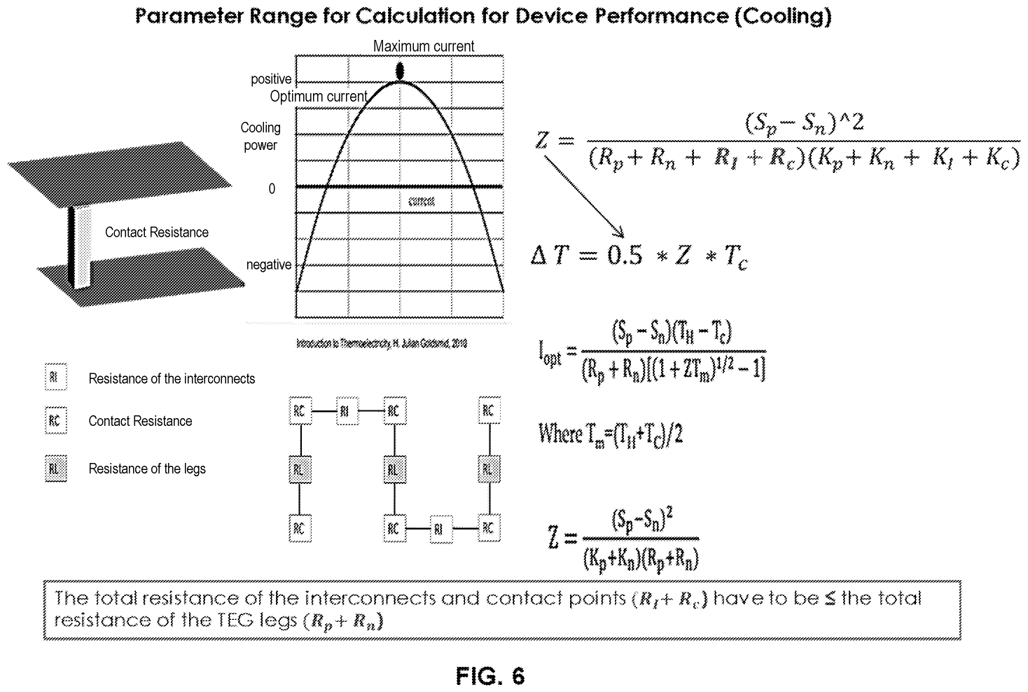

FIG. 6 shows the corresponding equation that correlates the thermoelectric temperature gradient with the series resistance of the TE legs, interconnects, contact resistance of the legs with interconnects and the optimum current. The performance of the TEC device is affected by the illustrated relationship.

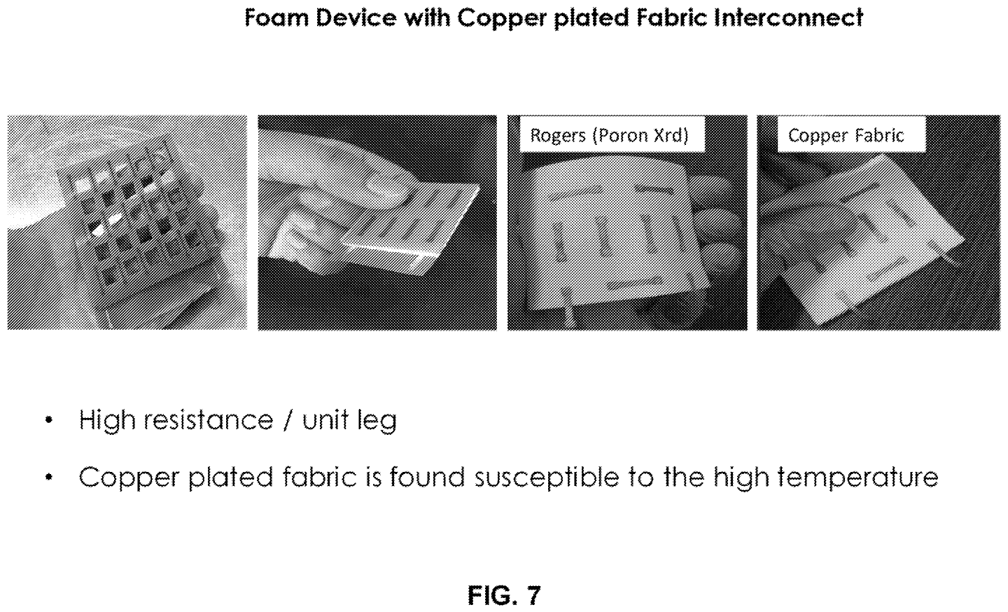

FIG. 7 shows the chronological development of TEC device made with TE legs soldered on pyralux film, and then the legs are inserted into the nonwoven materials with pyralux film connectors, and the legs are inserted into thermally stable foam with copper foil/copper plated fabric interconnects. The copper plated fabric used for the conductive interconnections allows for more flexibility of the fabricated device. The image on the left illustrates openings (or holes) passing through the foam block between the interconnections to aid in the flexibility of the TEC device.

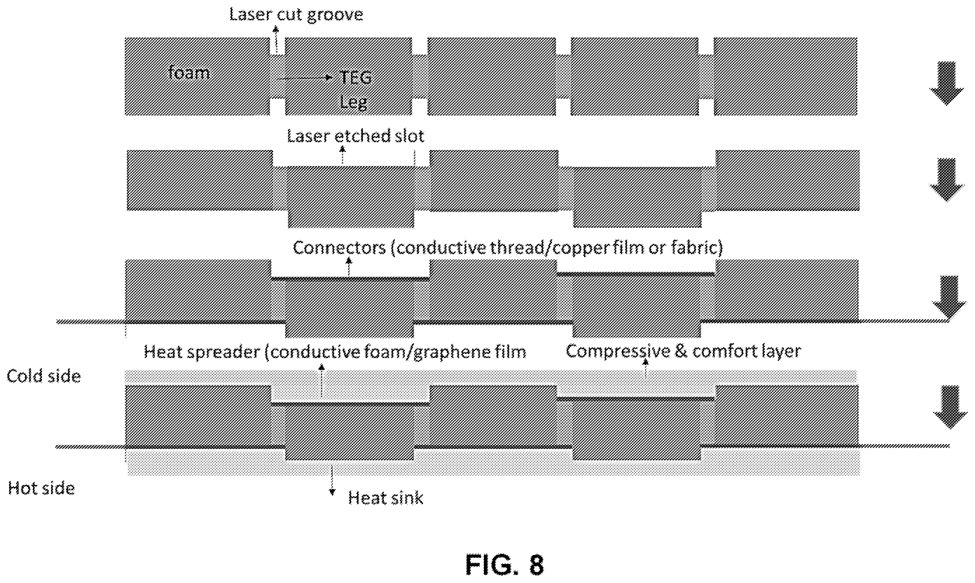

FIG. 8 shows step by step fabrication process of the foam-based TEC device where a first step is to laser cut the holes to insert the TE legs and next to etch (or cut) the foam forming slots that receive the interconnects and solder paste. After soldering the interconnects to ends of the TE legs, the thermally conductive soft materials can be placed in the same slots for thermal spreading and cushioning of the legs. A heat sink layer and/or heat spreader layer can then be applied to one or both surfaces of the TEC device.

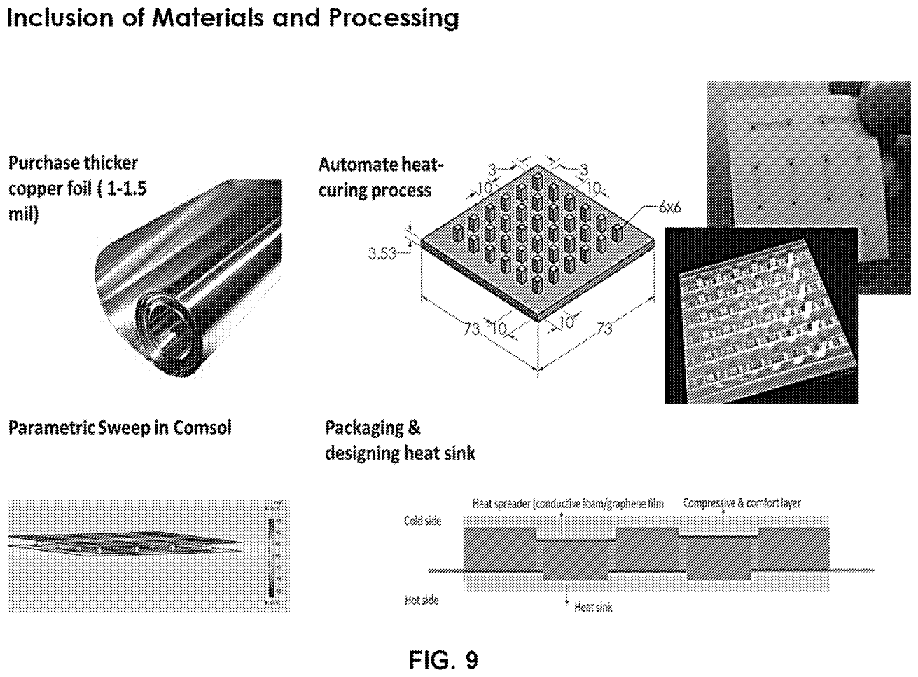

FIG. 9 shows from the top left, that a range of thickness of copper foil can be used as the interconnects of the TE legs, and on the top right, the figure shows an example of the custom-built metal-piece developed for the localized sintering of interconnects (e.g., copper foil with the TE legs). The images illustrate the slots for receiving the interconnections. In the lower left, the figure shows the finite element modeling of a TEC cooling device and on the right side the figure shows the cross-sectional image of the fully packaged TEC device.

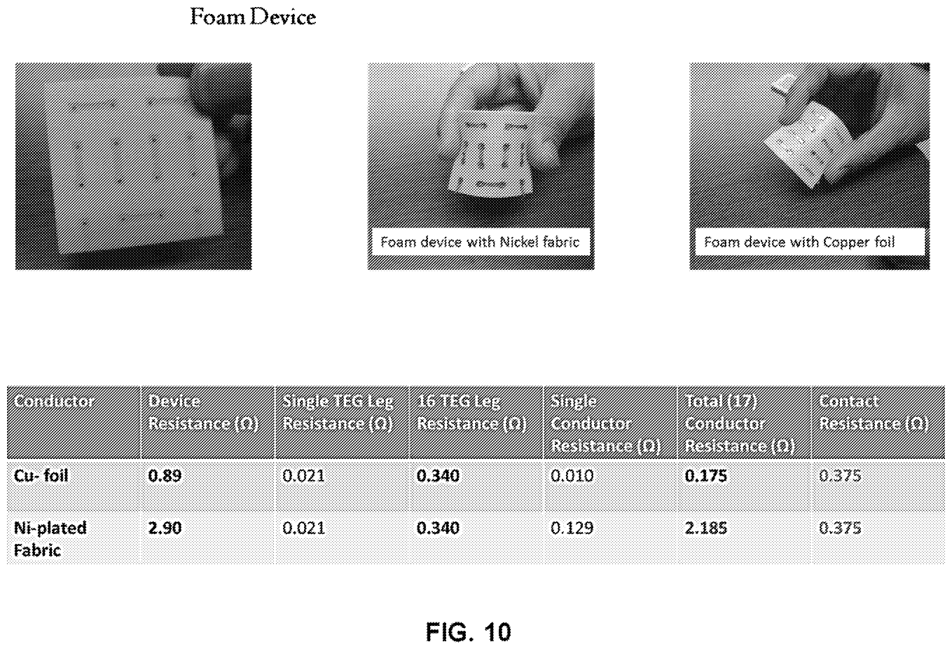

FIG. 10 shows the comparative analysis of the total resistance of the same size TEC devices made with copper foil interconnects and nickel coated conductive fabric interconnects. The images of the 4×4 foam based TEC device illustrates its ability to conform to different shapes.

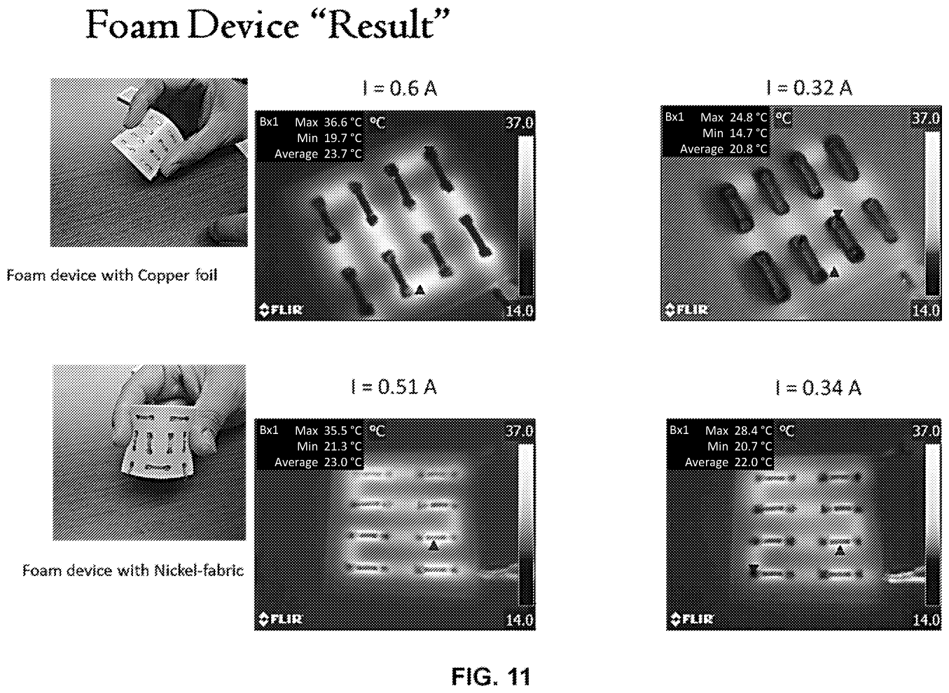

FIG. 11 shows infrared thermal images of foam based TEC device made with copper foil interconnects and nickel fabric interconnects. The result shows that the lower resistance of TEC device made with copper foil interconnects enables a higher rate of cooling.

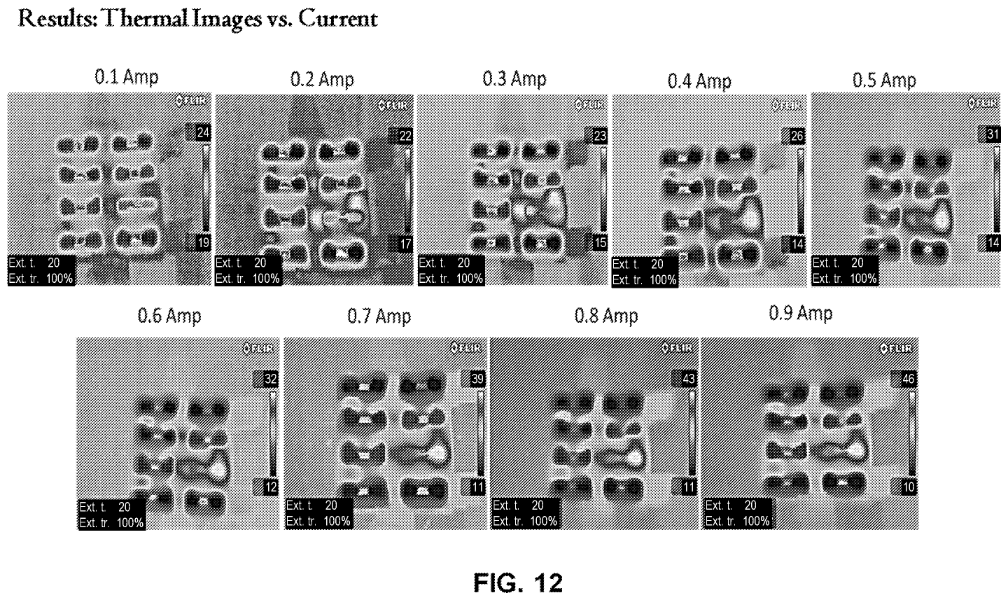

FIG. 12 shows infrared thermal images illustrating the variation of the cooling temperature of the TEC device with the increase of the current through the device. The device was placed on a block of aluminum (heat sink).

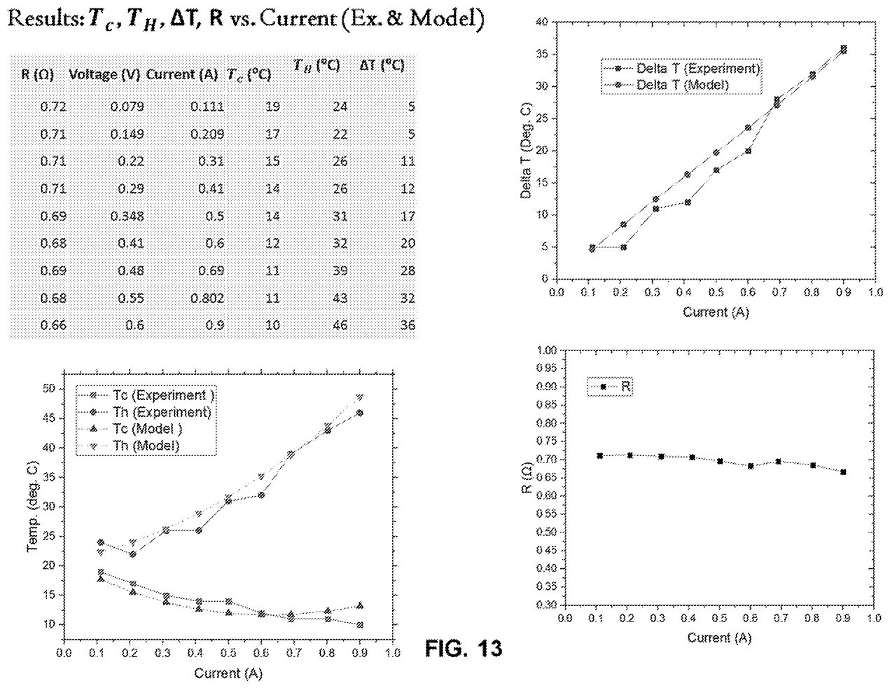

FIG. 13 shows the graphical representation of cold side temperature, hot side temperature, temperature differential and the resistance of the TEC device (copper interconnect) with the increase of current flow through the device.

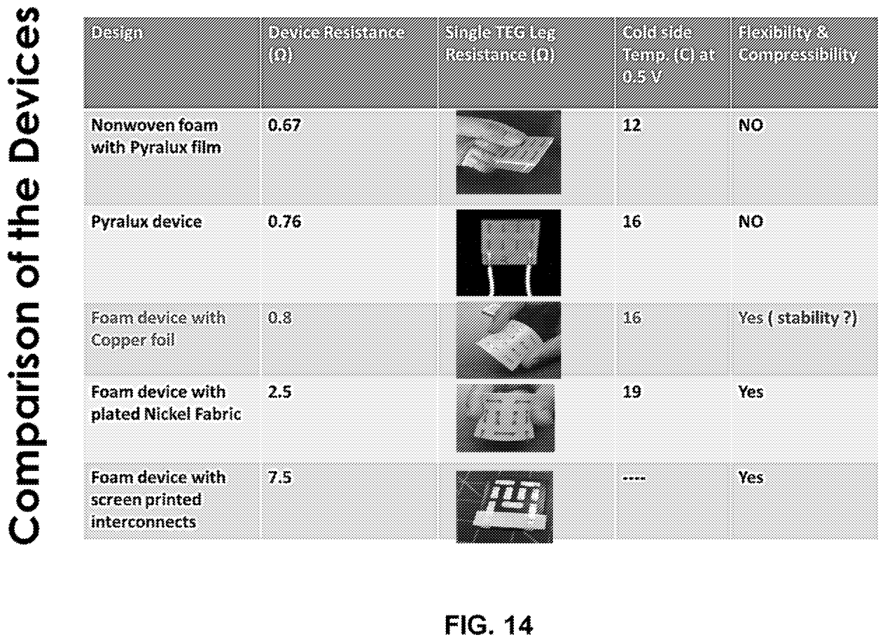

FIG. 14 shows the comparative analysis of the different versions of TEC device developed with different materials and integration system. As previously noted, the copper foil interconnects resulted in the most effect on cooling.

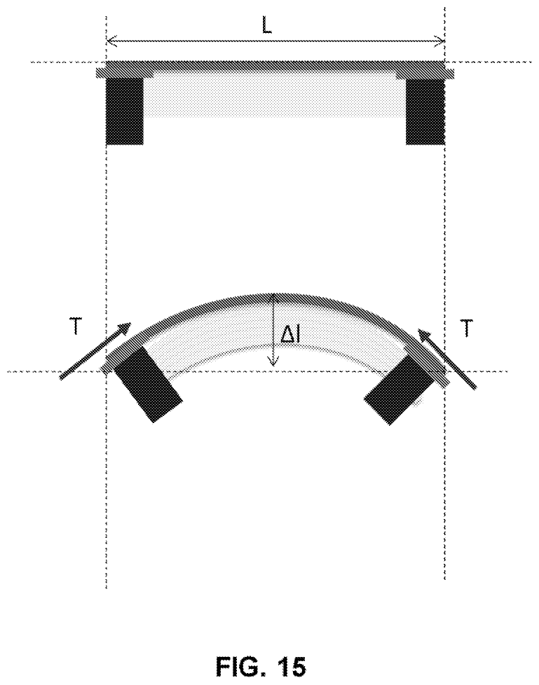

FIG. 15 shows the stress concentration at the connection points of the interconnects and the TE legs through the development of pulling tension while the device is bent.

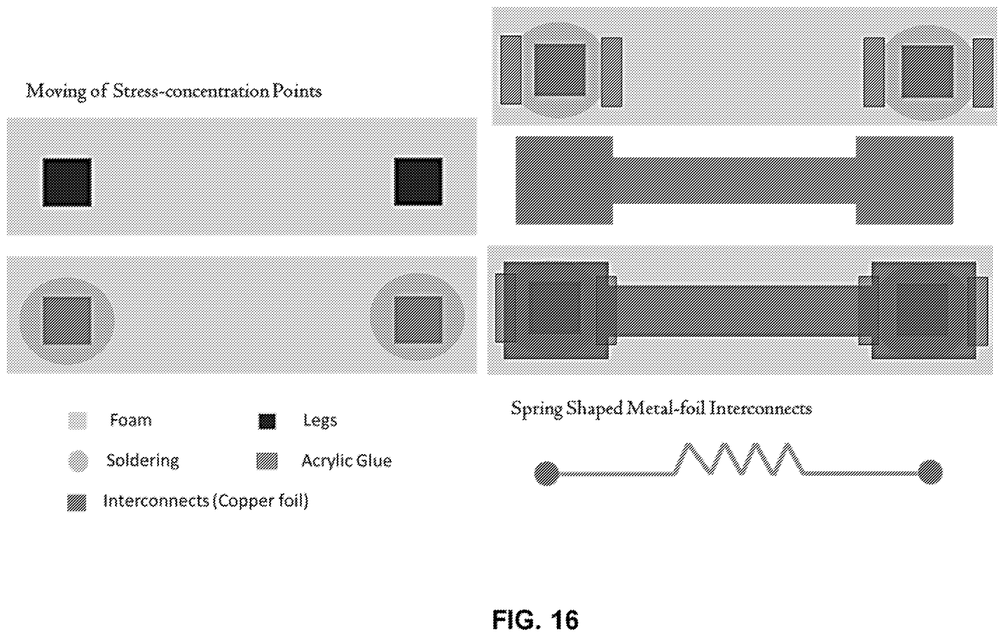

FIG. 16 shows the integration process of adhesive material around the soldering area of the interconnect and the leg connection (junctions) to mitigate the stress concentration at the junctions. The TE legs are inserted though the openings in the foam, and solder is applied to the ends for connection with the conductive connectors. The adhesive material (e.g., acrylic glue) is applied on opposite sides of the solder and the interconnect is affixed across the TE legs over the adhesive material. The figure at the bottom right corner shows a side view of the crimped (spring shaped) metal foil interconnect which is capable of extending when the device is bent.

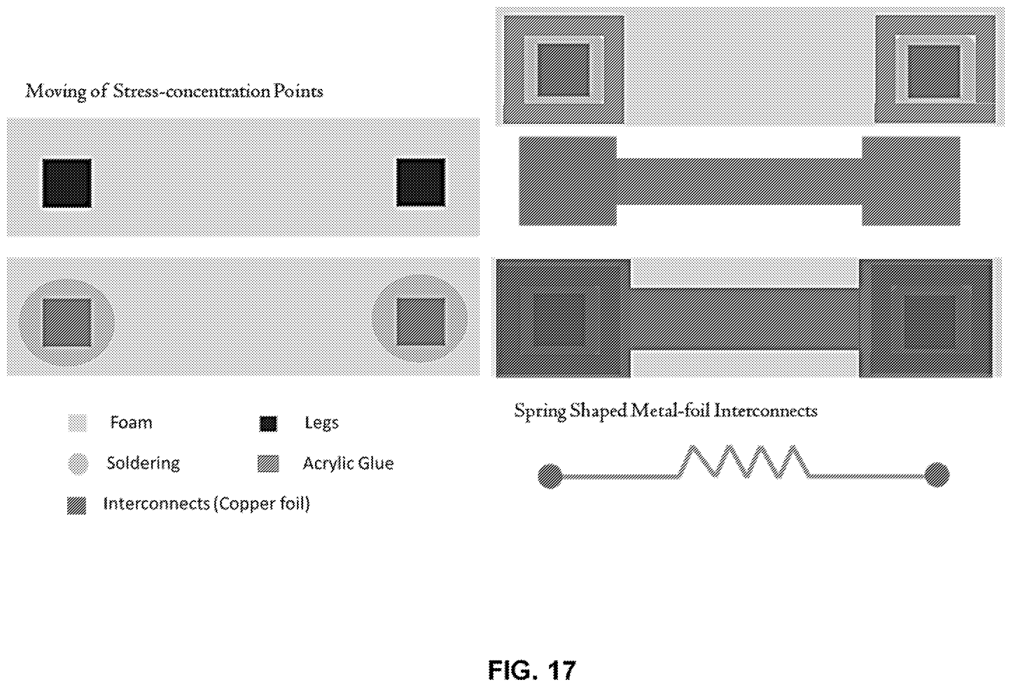

FIG. 17 shows the set-up of the TEC device on a foam material with the integration of the thermal spreading layer. In this example, the adhesive material is applied around the solder to affix the interconnect.

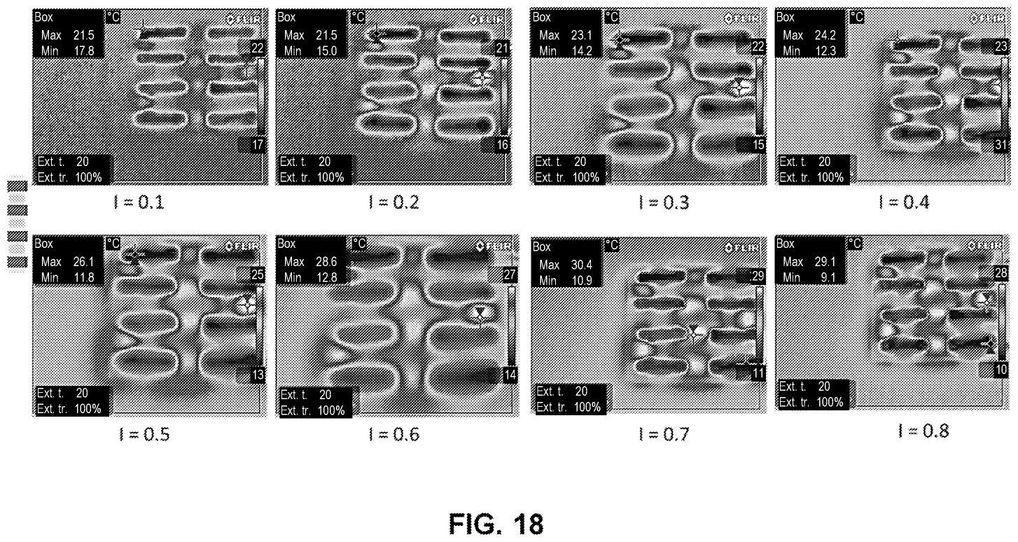

FIG. 18 shows IR thermal images of the cold side of the TEC device with the increase of the current through the device. The device was evaluated on a foam block and without the integration of the thermal spreading layer.

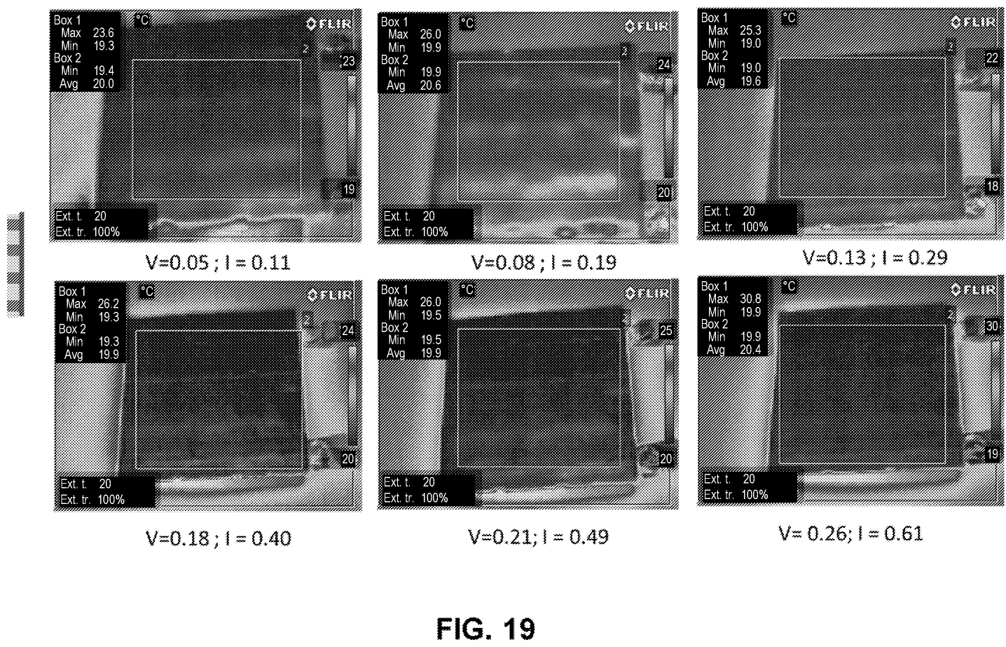

FIG. 19 shows IR thermal images of the cold side of the TEC device of FIG. 18 with the increase of the current through the device. The device was integrated with the thermal spreading layer and evaluated on a foam block. The thermal spreading layer increases the area of the cooling.

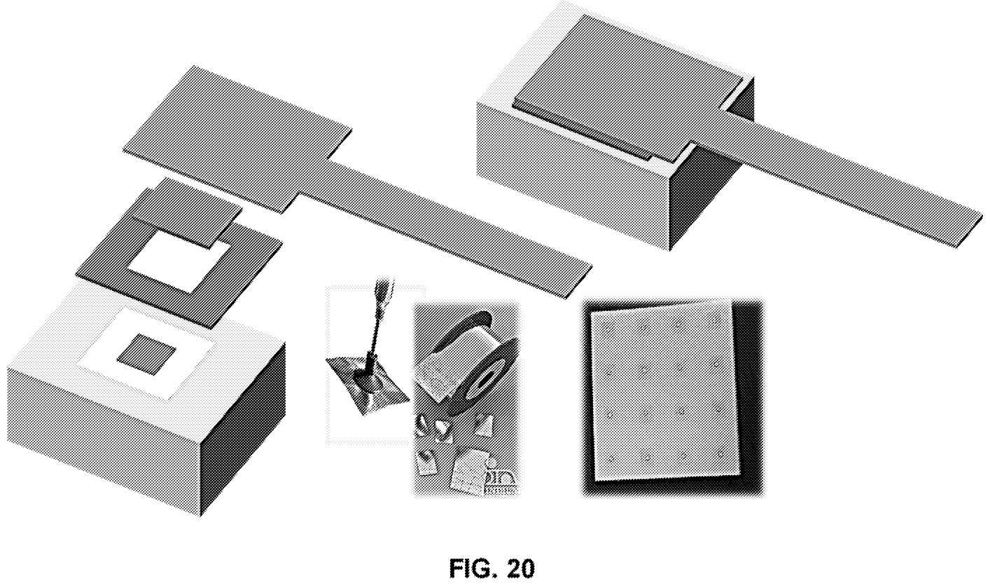

FIG. 20 shows the integration process of thermal adhesive film layer around the TE leg areas.

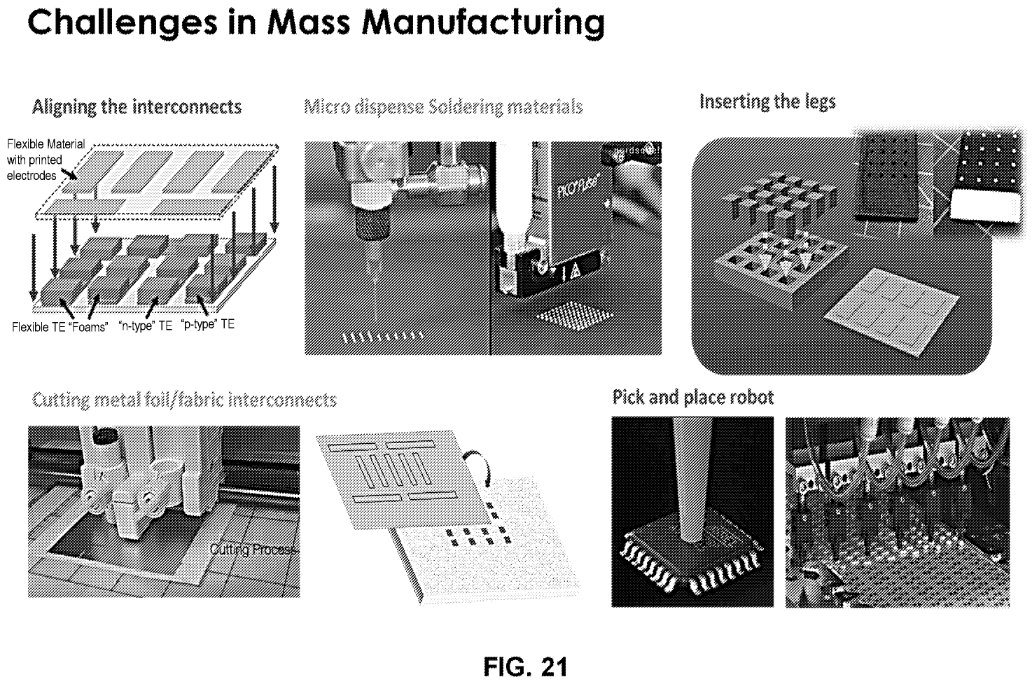

FIG. 21 shows an example of the manufacturing process of inserting TE legs with a pick-and-place robot, dispensing of the solder, and the process of die-cutting the thin-metal foil to make the interconnects and positioning the interconnects.

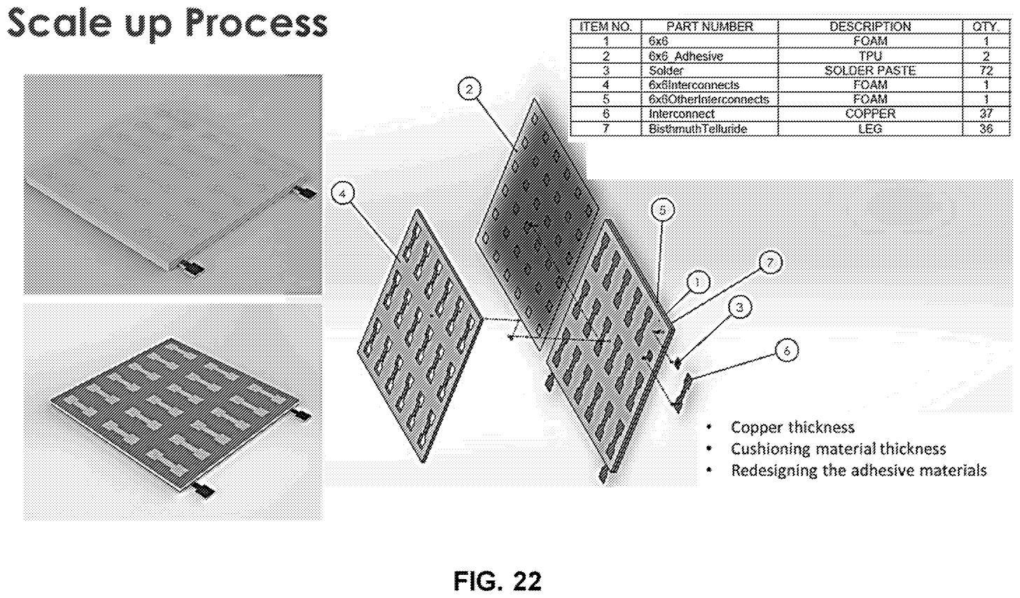

FIG. 22 shows the individual layers of a 6×6 (36 total TE legs) TEC foam-device, and a listing of its associated components.

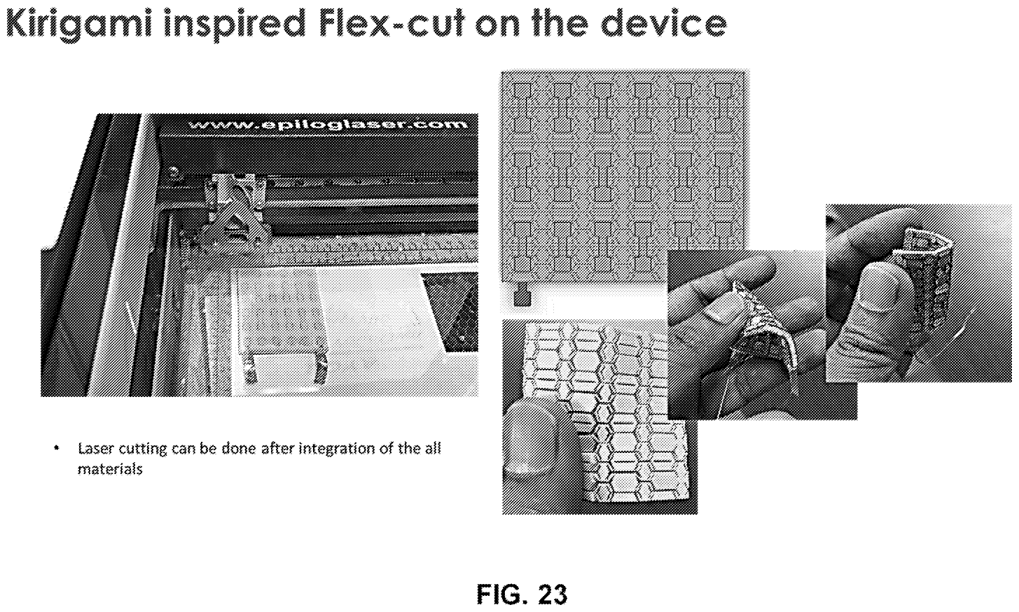

FIG. 23 shows an example of a laser cutting process for creating a Kirigami cut-design around the legs and interconnects of the TEC device to increase the flexibility of the device.

In some implementations, openings or voids can be formed between the interconnects to assist in flexibility of the device.

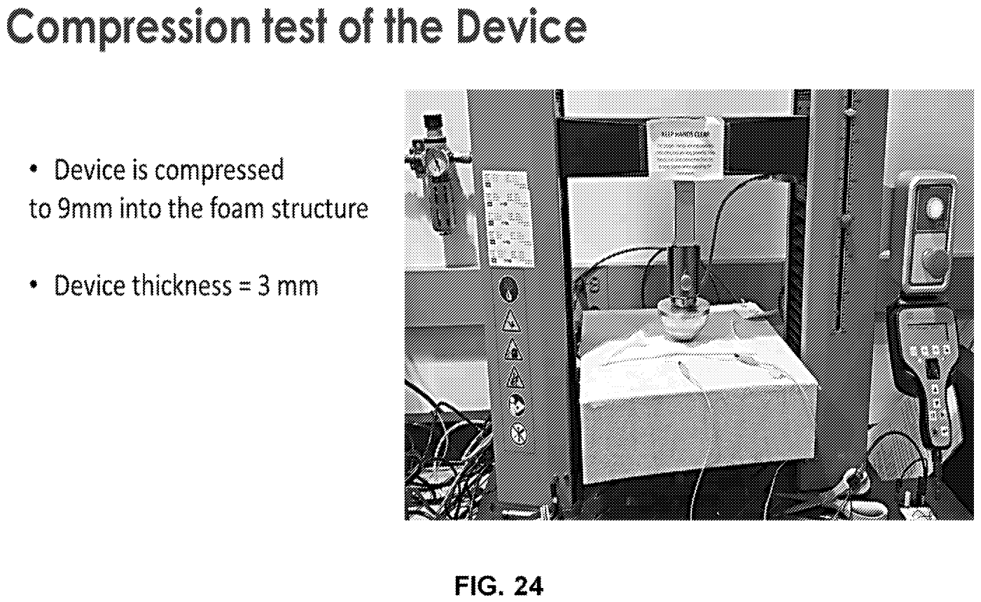

FIG. 24 shows an example of the mechanical compression (compressed & bent) test of the device when it is place on a foam (e.g. a mattress).

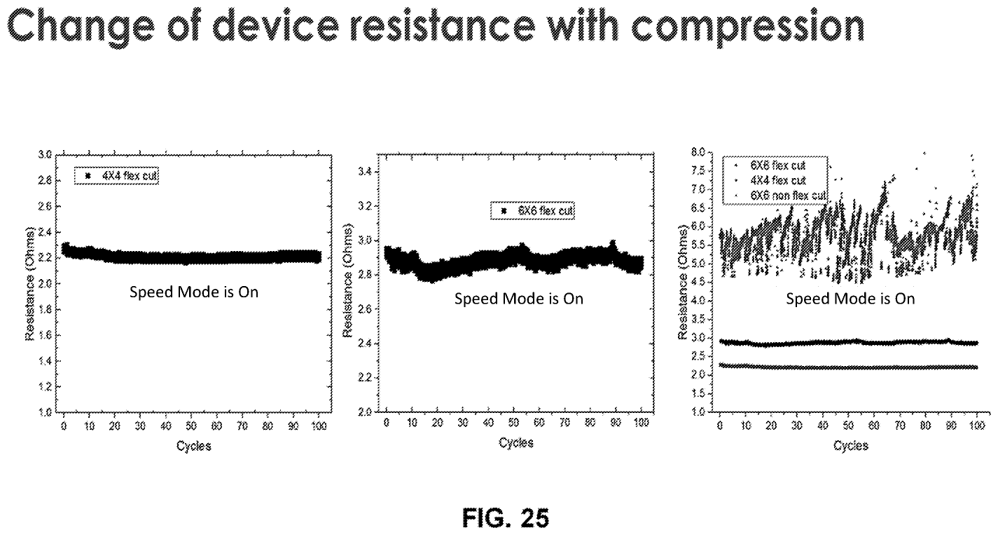

FIG. 25 shows that the resistance of the kirgami-cut or flex cut around the legs and interconnects of TEC provide the bendability and compressibility to the device. The mechanical compression test data shows that the device with flex-cut has a very insignificant change of the internal resistance after compressing the device's integrated foam (50% compression) to 6000 cycles.

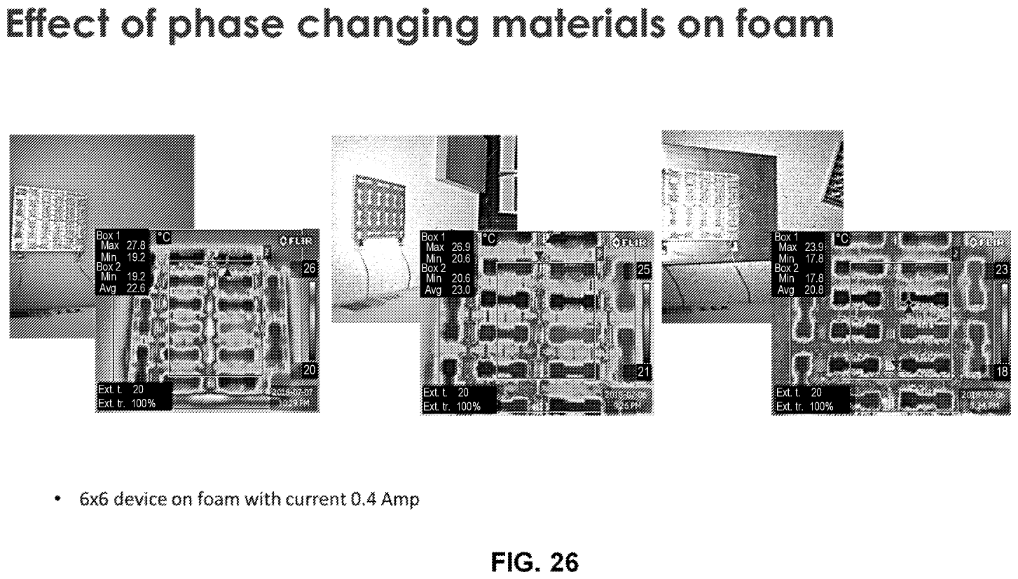

FIG. 26 shows the thermal image measurement set up of the 6×6 flex-cut TEC devices.

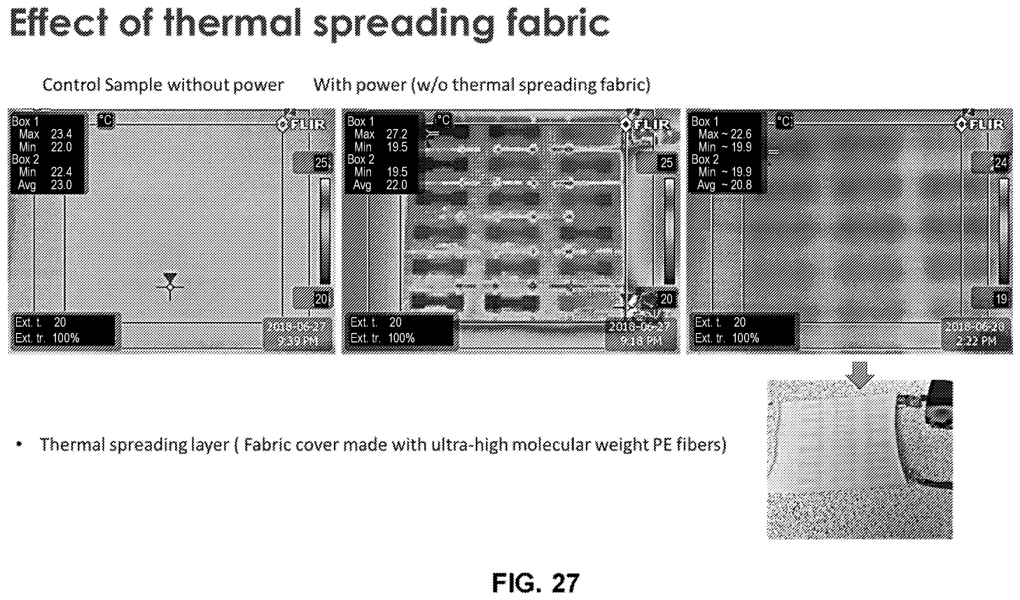

FIG. 27 shows the comparison of the thermal images of the TEC device tests on a foam mattress with and without a thermal spreading layer (e.g., a thermally conductive fabric).

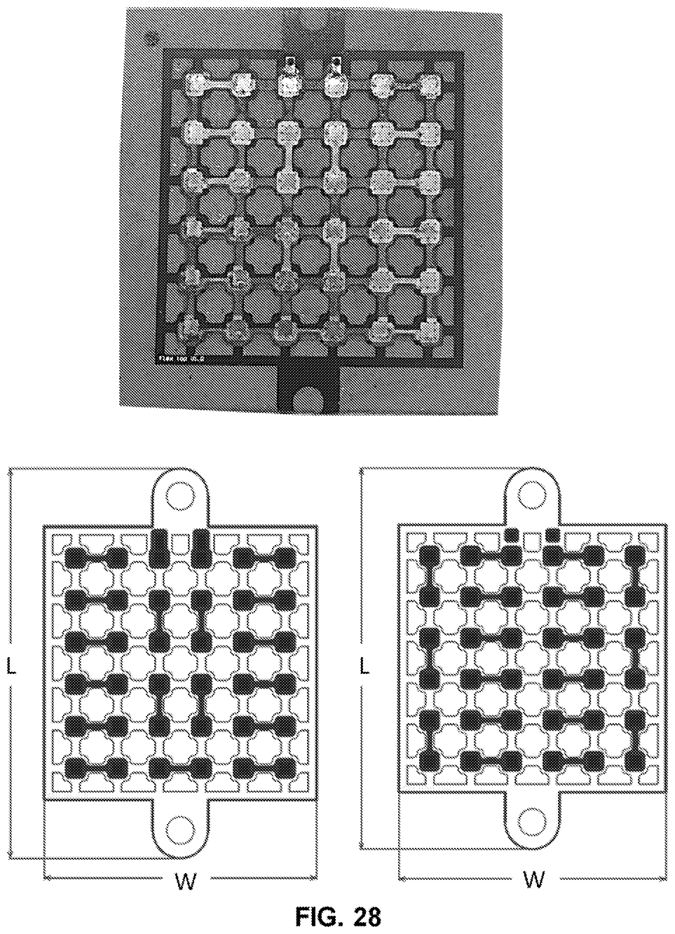

FIG. 28 shows an image of an example of a TEG (or TEC) device with schematic diagrams illustrating the interconnect locations on the imaged side (left) and the opposite side (right) of the device. The interconnects extend between TE legs across a base layer (e.g., a preprinted flexible printed circuit board) on the foam. The grid arrangement of the base layer can provide durability while maintaining flexibility of the TEC device. In this configuration, the base layer includes a border that extends around the interconnects.

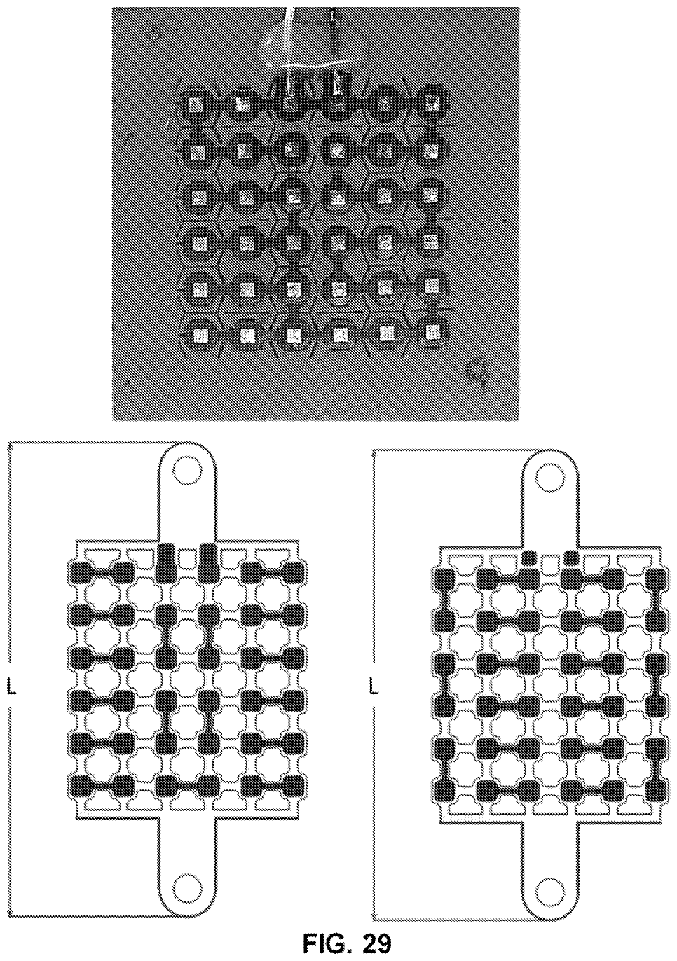

FIG. 29 shows an image of an example of a TEG (or TEC) device with schematic diagrams illustrating the interconnect locations on the imaged side (left) and the opposite side (right) of the device. The interconnects extend between TE legs across a base layer. In this configuration, size of the base layer has been reduced by eliminating the border around the interconnects. In addition, the base layer is arranged to be consistent with the locations of the interconnects. This reduction in cross-members can increase the flexibility of the device.

FIG. 30 shows an image of an example of a TEG (or TEC) device with portions of the foam removed between the interconnects. For example, the foam block can be a flexible printed circuit board that supports the TE legs and conductive interconnects. This arrangement can maximize the ability of the TEC to conform to the shape of a surface.

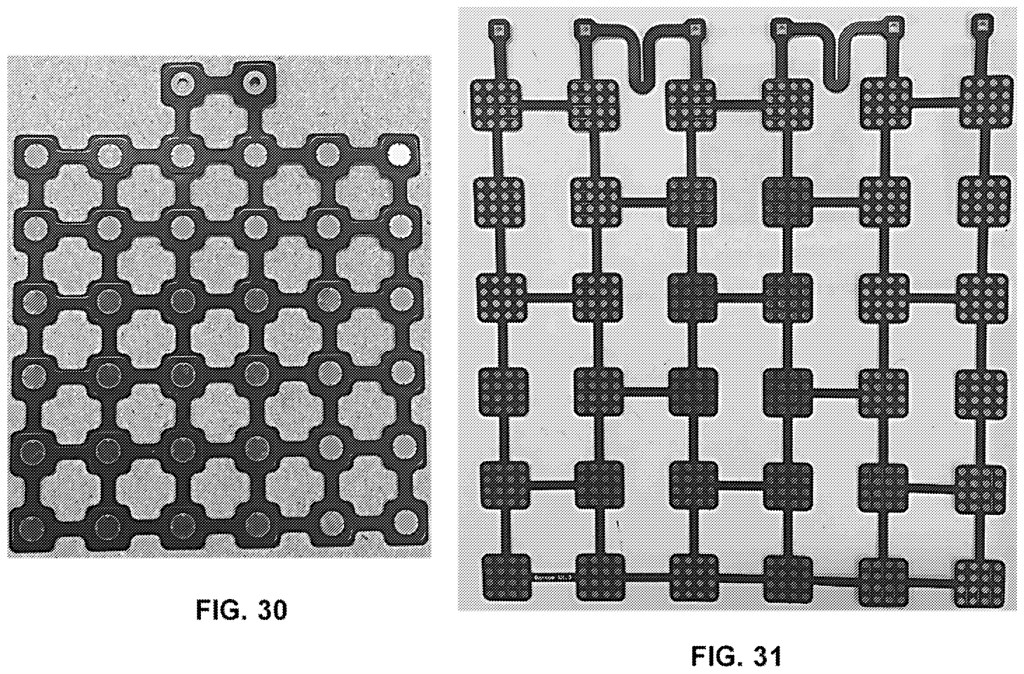

FIG. 31 shows an image of an example of a TEG (or TEC) device having interconnected TEG subsections. The TEG subsections comprise 4×4 TEGs that have been reduced in size. A base layer connects the TEG subsections through conductive connections in the base layer. The base layer provides structural support and distribution of the TEG subsections. The reduced size of the TEG subsections and the interconnection of the base layer allows the overall device to conform to the shape of a surface.

It should be emphasized that the above-described embodiments of the present disclosure are merely possible examples of implementations set forth for a clear understanding of the principles of the disclosure. Many variations and modifications may be made to the above-described embodiment(s) without departing substantially from the spirit and principles of the disclosure. All such modifications and variations are intended to be included herein within the scope of this disclosure and protected by the following claims.

1. A flexible thermoelectric generator (TEG) comprising:
a foam block comprising:
vertical voids, wherein the vertical voids extend from a top surface to a bottom surface of the foam block; and
horizontal voids, wherein each horizontal void extends into the foam block a depth as measured from either the top surface of the foam block or the bottom surface of the foam block, wherein the horizontal voids do not extend completely from the top surface of the foam block to the bottom surface of the foam block, wherein each horizontal void extends a distance along the top surface or the bottom surface of the foam block, wherein at least one end of each horizontal void overlaps a vertical void, wherein each end of at least one of the horizontal voids overlaps a vertical void;
TE legs, wherein each TE leg is contained in a vertical void, wherein the TE leg has a first surface at a first end of the TE leg and a second surface at a second end of the TE leg, wherein the first end is opposite the second end of the TE leg, wherein the entire TE leg except for the first surface and the second surface is in direct contact with the foam block, wherein the first surface of the TE leg is level with the bottom of a horizontal void extending into the top surface of the foam block, and wherein the second surface of the TE leg is level with the bottom of a horizontal void extending into the bottom surface of the foam block; and
conductive connectors, wherein each conductive connector is layered on the bottom of a horizontal void, wherein at least one end of each conductive connector is coupled to the first surface or the second surface of at least one of the TE legs, wherein a thickness of each conductive connector is less than the depth of the horizontal void.

2. The flexible TEG of claim 1, further comprising:
heat spreading material blocks, wherein each heat spreading material block is placed in the horizontal void on top of the conductive connector present in the horizontal void, wherein a bottom surface of each heat spreading material block is in direct contact with at least the conductive connector present in the horizontal void and a top surface of each heat spreading material block is level with either the bottom surface of the foam block or the top surface of the foam block.

3. The flexible TEG of claim 2, further comprising a heat sink, wherein the heat sink is in direct contact with the top surface or the bottom surface, but not both surfaces, of the foam block and is in direct contact with the heat spreading material blocks that are level with the surface of the foam block that is in direct contact with the heat sink, wherein the heat sink forms an outer layer of the flexible TEG.

4. The flexible TEG of claim 3, further comprising a compressive material layer, wherein the compressive material layer is in direct contact with the top surface or the bottom surface, but not both surfaces, of the foam block and is in direct contact with the heat spreading material blocks that are level with the surface of the foam block that is in direct contact with the compressive material layer, wherein the compressive material layer forms an outer layer of the flexible TEG opposite of the heat sink.

5. The flexible TEG of claim 1, further comprising a compressive material layer, wherein the compressive material layer is in direct contact with the top surface or the bottom surface, but not both surfaces, of the foam block and is in direct contact with the heat spreading material blocks that are level with the surface of the foam block that is in direct contact with the compressive material layer, wherein the heat compressive material layer forms an outer layer of the flexible TEG.

6. The flexible TEG of claim 1, wherein at least one of the horizontal voids extends to an edge of the foam block and wherein the conductive connector in contact with the bottom surface of the horizontal void that extends to the edge of the foam block extends a distance past the edge of the foam block and is configured to couple to a power source.

7. The flexible TEG of claim 6, wherein at least one additional horizontal void extends to the edge of the foam block and wherein the conductive connector in contact with the bottom surface of the horizontal void that extends to the edge of the foam block extends a distance past the edge of the foam block and is configured to couple to a power source.

8. The flexible TEG device of claim 1, wherein the foam block further comprises patterned scoring on the top surface, bottom surface, or both the top and the bottom surface of the foam block.

9. The flexible TEG device of claim 1, wherein the foam block comprises a polymer, a textile, or a combination of a polymer and a textile thereof.

10. The flexible TEG device of claim 1, wherein the conductive connectors comprise a conductive film or a filament of metals, a printed material composed of a metallic ink or an ink-polymer composite, a polymer film, or any combination thereof.

11. The flexible TEG device of claim 1, wherein at least one of the TE legs is an N-type TE leg or a P-type leg.

12. (canceled)

13. The flexible TEG device of claim 2, wherein the heat spreading material block comprises a metal, a polymer composite, a metal or graphene coated material, a carbon or graphene-based thermally conductive films, a highly conductive polymer film, a soft rubbery material that can be loaded with ceramic particles or materials, or any combination thereof.

14. The flexible TEG device of claim 3, wherein the heat sink comprises a metal, a polymer composite, a metal or graphene coated material, a carbon or graphene-based thermally conductive films, a highly conductive polymer film, a soft rubbery material that can be loaded with ceramic particles or materials, or any combination thereof.

15. The flexible TEG device of claim 4, wherein the compressive material layer comprises: a polymer, a textile, or a combination of a polymer and a textile.

16. The flexible TEG device of claim 1, wherein a total resistance across all the conductive connectors and contact resistance between the conductive connectors and the TE legs is less than a total resistance of the TE legs.

17-20. (canceled)

21. A method of manufacturing a flexible TEG device, the method comprising:
forming vertical voids in a foam block, wherein the vertical voids extend from a top surface to a bottom surface of the foam block;
forming horizontal voids in the foam block, wherein each horizontal void extends into the foam block a depth as measured from either the top surface of the foam block or the bottom surface of the foam block, wherein the horizontal voids do not extend completely from the top surface of the foam block to the bottom surface of the foam block, wherein each horizontal void extends a distance along the top surface or the bottom surface of the foam block, wherein at least one end of each horizontal void overlaps a vertical void, wherein each end of at least one of the horizontal voids overlaps a vertical void;
inserting a plurality TE legs into a plurality of the vertical voids, wherein a single TE leg is inserted per vertical void, wherein the TE leg has a first surface at a first end of the TE leg and a second surface at a second end of the TE leg, wherein the first end is opposite the second end of the TE leg, wherein the entire TE leg except for the first surface and the second surface is in direct contact with the foam block, wherein the first surface of the TE leg is level with the bottom of a horizontal void extending into the top surface of the foam block, and wherein the second surface of the TE leg is level with the bottom of a horizontal void extending into the bottom surface of the foam block; and
connecting pairs of TE legs in the plurality of TE legs with conductive connectors, wherein each conductive connector is layered on the bottom of a horizontal void, wherein at least one end of each conductive connector is coupled to a first surface or a second surface of a TE leg and wherein the other end of each conductive connector is coupled to a first surface or a second surface of a different TE leg in the plurality of TE legs, wherein a thickness of each conductive connector is less than the depth of the horizontal void.

22. The method of claim 21, further comprising coupling a heat spreading material block to the foam block, wherein each heat spreading material block is placed in the horizontal void on top of the conductive connector present in the horizontal void, wherein a bottom surface of each heat spreading material block is in direct contact with the heat spreading material block and a top surface of each heat spreading material block is level with either the bottom surface of the foam block or the top surface of the foam block.

23. The method of claim 22, further comprising coupling a heat sink to the foam block, wherein the heat sink is in direct contact with the top surface or the bottom surface, but not both surfaces, of the foam block and is in direct contact with the heat spreading material blocks that are level with the surface of the foam block that is in direct contact with the heat sink, wherein the heat sink forms an outer layer of the flexible TEG.

24. The method of claim 23, further comprising coupling a compressive material layer to the foam block, wherein the compressive material layer is in direct contact with the top surface or the bottom surface, but not both surfaces, of the foam block and is in direct contact with the heat spreading material blocks that are level with the surface of the foam block that is in direct contact with the compressive material layer, wherein the compressive material layer forms an outer layer of the flexible TEG opposite of the heat sink.

25-26. (canceled)

27. The method of claim 21, further comprising etching or cutting a pattern on the top surface, bottom surface, or both the top and the bottom surface of the foam block.

28-35. (canceled)
